(19) United States
(12) Patent Application Publication
(10) Pub. No.: US 2024/0048115 A1
(43) Pub. Date: Feb. 8, 2024

(54) ACOUSTIC WAVE DEVICE AND METHOD OF MANUFACTURING ACOUSTIC WAVE DEVICE

(71) Applicant: Murata Manufacturing Co., Ltd., Nagaokakyo-shi (JP)

(72) Inventor: Kazunori INOUE, Nagaokakyo-shi (JP)

(21) Appl. No.: 18/381,205

(22) Filed: Oct. 18, 2023

Related U.S. Application Data
(63) Continuation of application No. PCT/JP2022/018227, filed on Apr. 19, 2022.
(60) Provisional application No. 63/177,623, filed on Apr. 21, 2021.

(51) Int. Cl. H03H 9/02; H03H 3/02; H03H 9/13; H03H 9/17

(52) U.S. Cl. CPC H03H 9/02133; H03H 3/02; H03H 9/02031; H03H 9/02102; H03H 9/02228; H03H 9/132; H03H 9/173; H03H 9/174; H03H 9/176; H03H 2003/021; H03H 2003/023

(57) ABSTRACT

An acoustic wave device includes a support substrate with a thickness in a first direction, a piezoelectric layer above or below the support substrate, a functional electrode on or above the piezoelectric layer, and a stress-relaxing layer. In a plan view in the first direction, a hollow portion at least partly overlaps the functional electrode between the support substrate and the piezoelectric layer, and the stress-relaxing layer overlaps an outer edge of the hollow portion. Alternatively, in a plan view in the first direction, the stress-relaxing layer is outside at least a portion of the outer edge of the hollow portion and is interposed between the support substrate and the piezoelectric layer.

### CROSS REFERENCE TO RELATED APPLICATIONS

This application claims the benefit of priority to Provisional Application No. 63/177,623 filed on Apr. 21, 2021 and is a Continuation Application of PCT Application No. PCT/JP2022/018227 filed on Apr. 19, 2022. The entire contents of each application are hereby incorporated herein by reference.

### BACKGROUND OF THE INVENTION

### 1. Field of the Invention

The present disclosure relates to an acoustic wave device and a method of manufacturing an acoustic wave device.

### 2. Description of the Related Art

Japanese Unexamined Patent Application Publication No. 2012-257019 discloses an acoustic wave device.

### SUMMARY OF THE INVENTION

In Japanese Unexamined Patent Application Publication No. 2012-257019, a portion (a membrane portion) of a piezoelectric layer that overlaps a hollow portion is in contact with a support member (an intermediate layer or a support substrate), and a crack can appear.

Preferred embodiments of the present invention reduce or prevent cracking of a piezoelectric layer.

An acoustic wave device according to an aspect of a preferred embodiment of the present invention includes a support substrate with a thickness in a first direction, a piezoelectric layer above or below the support substrate, a functional electrode in or on the piezoelectric layer, and a stress-relaxing layer. In a plan view in the first direction, a hollow portion at least partly overlaps the functional electrode between the support substrate and the piezoelectric layer. In a plan view in the first direction, the stress-relaxing layer overlaps an outer edge of the hollow portion or is outside at least a portion of the outer edge of the hollow portion and is interposed between the support substrate and the piezoelectric layer.

A method of manufacturing an acoustic wave device according to an aspect of a preferred embodiment of the present invention includes stacking a support substrate with a thickness in a first direction and a piezoelectric layer, forming a functional electrode in or on the piezoelectric layer after the stacking, etching the piezoelectric layer in an outer region outside a region in which the functional electrode is formed, forming a stress-relaxing layer such that the stress-relaxing layer at least partly overlaps the piezoelectric layer after the etching, and forming a hollow portion such that the stress-relaxing layer is exposed.

According to preferred embodiments of the present disclosure, cracking of piezoelectric layers is reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view of an acoustic wave device according to a preferred embodiment of the present invention.

FIG. 1B is a plan view of an electrode structure according to a preferred embodiment of the present invention.

FIG. 2 is a sectional view of a portion taken along line II-II in FIG. 1A.

FIG. 3A is a sectional view for schematically illustrating a Lamb wave that propagates through a piezoelectric layer in a comparative example.

FIG. 3B is a sectional view for schematically illustrating a bulk wave that propagates through a piezoelectric layer according to a preferred embodiment of the present invention in a first thickness-shear mode.

FIG. 4 is a sectional view for schematically illustrating the amplitude direction of the bulk wave that propagates through a piezoelectric layer according to a preferred embodiment of the present invention in the first thickness-shear mode.

FIG. 5 illustrates an example of resonance characteristics of an acoustic wave device according to a preferred embodiment of the present invention.

FIG. 6 illustrates the relationship between d/2p and the fractional band width of an acoustic wave device according to a preferred embodiment of the present invention that serves as a resonator where p is a distance between centers of adjacent electrodes or the average distance of distances between centers, and d is the average thickness of the piezoelectric layer.

FIG. 7 is a plan view for illustrating an example in which an acoustic wave device according to a preferred embodiment of the present invention includes a pair of electrodes.

FIG. 8 is a reference graph illustrating an example of the resonance characteristics of an acoustic wave device according to the present preferred embodiment of the present invention.

FIG. 9 is a graph illustrating the relationship between the phase rotation amount of the impedance of spurious normalized at 180 degrees as the magnitude of the spurious and the fractional band width in the case where an acoustic wave device according to a preferred embodiment of the present invention includes a large number of acoustic wave resonators.

FIG. 10 illustrates the relationship among d/2p, a metallization ratio MR, and the fractional band width.

FIG. 11 illustrates a map of the fractional band width for Euler angles (0°, θ, ψ) of LiNbO₃ when d/p is close to zero as much as possible.

FIG. 12 is a perspective view of an acoustic wave device according to a preferred embodiment of the present invention from which a portion is cut.

FIG. 13 is a plan view of an acoustic wave device according to a first preferred embodiment of the present invention.

FIG. 14 illustrates a section taken along line XIV-XIV in FIG. 13.

FIG. 15A illustrates a joining step in a method of manufacturing the acoustic wave device according to the first preferred embodiment of the present invention.

FIG. 15B illustrates an electrode forming step in the method of manufacturing the acoustic wave device according to the first preferred embodiment of the present invention.

FIG. 15C illustrates a piezoelectric layer etching step in the method of manufacturing the acoustic wave device according to the first preferred embodiment of the present invention.

FIG. 15D illustrates a stress-relaxing layer forming step in the method of manufacturing the acoustic wave device according to the first preferred embodiment of the present invention.

FIG. 15E illustrates a wiring electrode forming step in the method of manufacturing the acoustic wave device according to the first preferred embodiment of the present invention.

FIG. 15F illustrates a hollow forming step in the method of manufacturing the acoustic wave device according to the first preferred embodiment of the present invention.

FIG. 15G illustrates an intermediate layer etching step in the method of manufacturing the acoustic wave device according to the first preferred embodiment of the present invention.

FIG. 16 illustrates an example of a section of an acoustic wave device according to a second preferred embodiment of the present invention.

FIG. 17A illustrates a joining step in a method of manufacturing the acoustic wave device according to the second preferred embodiment of the present invention.

FIG. 17B illustrates an electrode forming step in the method of manufacturing the acoustic wave device according to the second preferred embodiment of the present invention.

FIG. 17C illustrates a piezoelectric layer etching step in the method of manufacturing the acoustic wave device according to the second preferred embodiment of the present invention.

FIG. 17D illustrates an intermediate layer first etching step in the method of manufacturing the acoustic wave device according to the second preferred embodiment of the present invention.

FIG. 17E illustrates a stress-relaxing layer forming step in the method of manufacturing the acoustic wave device according to the second preferred embodiment of the present invention.

FIG. 17F illustrates a wiring electrode forming step in the method of manufacturing the acoustic wave device according to the second preferred embodiment of the present invention.

FIG. 17G illustrates a hollow forming step in the method of manufacturing the acoustic wave device according to the second preferred embodiment of the present invention.

FIG. 17H illustrates an intermediate layer second etching step in the method of manufacturing the acoustic wave device according to the second preferred embodiment of the present invention.

FIG. 18 illustrates an example of a section of an acoustic wave device according to a third preferred embodiment of the present invention.

FIG. 19A illustrates a stress-relaxing layer forming step in a method of manufacturing the acoustic wave device according to the third preferred embodiment of the present invention.

FIG. 19B illustrates an intermediate layer forming step in the method of manufacturing the acoustic wave device according to the third preferred embodiment of the present invention.

FIG. 19C illustrates an intermediate layer flattening step in the method of manufacturing the acoustic wave device according to the third preferred embodiment of the present invention.

FIG. 19D illustrates a joining step in the method of manufacturing the acoustic wave device according to the third preferred embodiment of the present invention.

FIG. 19E illustrates a piezoelectric layer thinning step in in the method of manufacturing the acoustic wave device according to the third preferred embodiment of the present invention.

FIG. 19F illustrates an electrode forming step in the method of manufacturing the acoustic wave device according to the third preferred embodiment of the present invention.

FIG. 19G illustrates a wiring electrode forming step in the method of manufacturing the acoustic wave device according to the third preferred embodiment of the present invention.

FIG. 19H illustrates a hollow forming step in the method of manufacturing the acoustic wave device according to the third preferred embodiment of the present invention.

FIG. 19I illustrates an intermediate layer etching step in the method of manufacturing the acoustic wave device according to the third preferred embodiment of the present invention.

FIG. 19J illustrates a stress-relaxing layer portion removing step in the method of manufacturing the acoustic wave device according to the third preferred embodiment of the present invention.

FIG. 20 is a plan view of an acoustic wave device according to a fourth preferred embodiment of the present invention.

FIG. 21 illustrates a section taken along line XXI-XXI in FIG. 20.

FIG. 22A illustrates a joining step in a method of manufacturing the acoustic wave device according to the fourth preferred embodiment of the present invention.

FIG. 22B illustrates a piezoelectric layer etching step in the method of manufacturing the acoustic wave device according to the fourth preferred embodiment of the present invention.

FIG. 22C illustrates an electrode forming step in the method of manufacturing the acoustic wave device according to the fourth preferred embodiment of the present invention.

FIG. 22D illustrates a stress-relaxing layer forming step in the method of manufacturing the acoustic wave device according to the fourth preferred embodiment of the present invention.

FIG. 22E illustrates a wiring electrode forming step in the method of manufacturing the acoustic wave device according to the fourth preferred embodiment of the present invention.

FIG. 22F illustrates a sacrificial layer etching step in the method of manufacturing the acoustic wave device according to the fourth preferred embodiment of the present invention.

FIG. 23 is a plan view of an acoustic wave device according to a modification according to the fourth preferred embodiment of the present invention.

FIG. 24 illustrates a section taken along line XXIV-XXIV in FIG. 23.

### DETAILED DESCRIPTION OF THE PREFERRED EMBODIMENTS

Preferred embodiments of the present disclosure will hereinafter be described in detail based on the drawings. The preferred embodiments do not limit the present disclosure. The preferred embodiments of the present disclosure will be described by way of example. As for modifications, a second preferred embodiment, and subsequent preferred embodiments where structures can be partly replaced or combined between different preferred embodiments, the description of matters common to those according to a first preferred embodiment is omitted, and only differences will be described. In particular, the same actions and effects achieved by the same structures are not described for every preferred embodiment.

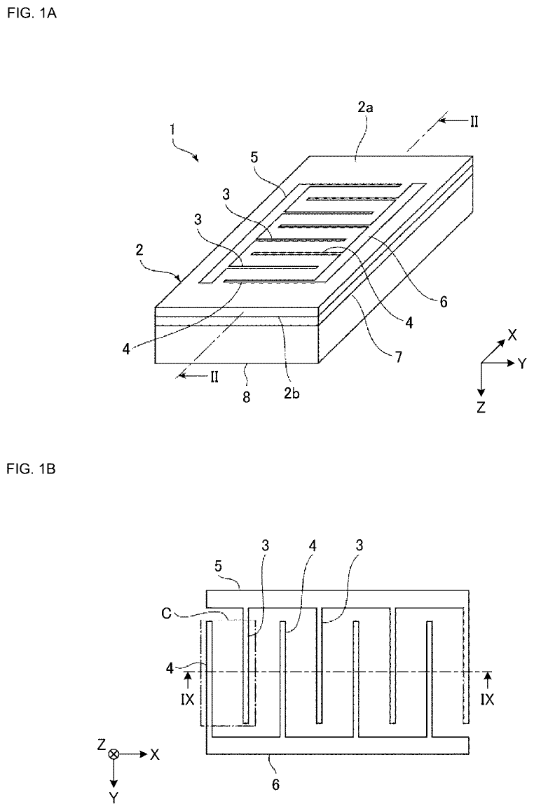

FIG. 1A is a perspective view of an acoustic wave device according to a preferred embodiment of the present invention. FIG. 1B is a plan view of an electrode structure according to the present preferred embodiment.

An acoustic wave device 1 according to the present preferred embodiment includes a piezoelectric layer 2 made of LiNbO₃. The piezoelectric layer 2 may be made of LiTaO₃. As for the cut-angles of LiNbO₃ and LiTaO₃, Z-cut is used according to the present preferred embodiment. As for the cut-angles of LiNbO₃ and LiTaO₃, rotated Y-cut or X-cut may be used. For example, a propagation direction of Y propagation and X propagation ±30° is preferable.

The thickness of the piezoelectric layer 2 is not particularly limited but is preferably no less than about 50 nm and no more than about 1000 nm to effectively excite a first thickness-shear mode, for example.

The piezoelectric layer 2 includes a first main surface 2a and a second main surface 2b that face away from each other in a Z-direction. Electrode fingers 3 and electrode fingers 4 are provided on the first main surface 2a.

The electrode fingers 3 are examples of a “first electrode finger”, and the electrode fingers 4 are examples of a “second electrode finger”. In FIG. 1A and FIG. 1B, the multiple electrode fingers 3 correspond to multiple “first electrode fingers” that are connected to a first busbar electrode 5. The multiple electrode fingers 4 correspond to multiple “second electrode fingers” that are connected to a second busbar electrode 6. The multiple electrode fingers 3 and the multiple electrode fingers 4 interdigitate with each other. Consequently, a functional electrode 30 that includes the electrode fingers 3, the electrode fingers 4, the first busbar electrode 5, and the second busbar electrode 6 is obtained. The functional electrode 30 is also referred to as an interdigital transducer electrode.

The electrode fingers 3 and the electrode fingers 4 each have a rectangular or substantially rectangular shape and each have a length direction. The electrode fingers 3 and the electrode fingers 4 adjacent to the electrode fingers 3 face each other in a direction perpendicular to the length direction. The length direction of the electrode fingers 3 and the electrode fingers 4 and the direction perpendicular to the length direction of the electrode fingers 3 and the electrode fingers 4 both are directions that intersect with a thickness direction of the piezoelectric layer 2. For this reason, it can be said that the electrode fingers 3 and the electrode fingers 4 adjacent to the electrode fingers 3 face each other in the direction that intersects with the thickness direction of the piezoelectric layer 2. In the following description, the thickness direction of the piezoelectric layer 2 is the Z-direction (or a first direction), the length direction of the electrode fingers 3 and the electrode fingers 4 is a Y-direction (or a second direction), and the direction perpendicular to the electrode fingers 3 and the electrode fingers 4 is an X-direction (or a third direction) in some cases.

The length direction of the electrode fingers 3 and the electrode fingers 4 may be interchanged with the direction perpendicular to the length direction of the electrode fingers 3 and the electrode fingers 4 illustrated in FIG. 1A and FIG. 1B. That is, in FIG. 1A and FIG. 1B, the electrode fingers 3 and the electrode fingers 4 may extend in a direction in which the first busbar electrode 5 and the second busbar electrode 6 extend. In this case, the first busbar electrode 5 and the second busbar electrode 6 extend in the direction in which the electrode fingers 3 and the electrode fingers 4 extend in FIG. 1A and FIG. 1B. Multiple paired structures in which the electrode fingers 3 connected to one potential and the electrode fingers 4 connected to the other potential are adjacent to each other are arranged in the direction perpendicular to the length direction of the electrode fingers 3 and the electrode fingers 4 described above.

The case where the electrode fingers 3 and the electrode fingers 4 are adjacent to each other, described herein, does not mean the case where the electrode fingers 3 and the electrode fingers 4 are in direct contact with each other but means the case where the electrode fingers 3 and the electrode fingers 4 are disposed with gaps interposed therebetween. When one of the electrode fingers 3 and one of the electrode fingers 4 are adjacent to each other, an electrode that is connected to a hot electrode or a ground electrode, including the other electrode fingers 3 and the other electrode fingers 4, is not disposed between the electrode finger 3 and the electrode finger 4. The number of pairs thereof is not necessarily an integer number of pairs but may be, for example, 1.5 pairs or 2.5 pairs.

A distance between the centers of the electrode finger 3 and the electrode finger 4, that is, a pitch preferably falls within the range of no less than about 1 μm and no more than about 10 μm, for example. The distance between the centers of the electrode finger 3 and the electrode finger 4 is a distance between the center of the width dimension of the electrode finger 3 in the direction perpendicular to the length direction of the electrode finger 3 and the center of the width dimension of the electrode finger 4 in the direction perpendicular to the length direction of the electrode finger 4.

In the case where at least the number of the electrode fingers 3 or the number of the electrode fingers 4 is more than one (in the case where there are 1.5 or more paired electrode sets when one of the electrode fingers 3 and one of the electrode fingers 4 are regarded as a paired electrode set), the distance between the centers of the electrode finger 3 and the electrode finger 4 means the average value of distances between the centers of the electrode fingers 3 and 4 adjacent to each other among the 1.5 pairs or more of the electrode fingers 3 and the electrode fingers 4.

The width of each of the electrode fingers 3 and the electrode fingers 4, that is, the dimension of each of the electrode fingers 3 and the electrode fingers 4 in a direction in which the electrode fingers 3 and the electrode fingers 4 face each other preferably falls within the range of no less than about 150 nm and no more than about 1000 nm, for example. The distance between the centers of the electrode finger 3 and the electrode finger 4 is a distance between the center of the dimension (width dimension) of the electrode finger 3 in the direction perpendicular to the length direction of the electrode finger 3 and the center of the dimension (width dimension) of the electrode finger 4 in the direction perpendicular to the length direction of the electrode finger 4.

According to the present preferred embodiment, a piezoelectric layer of Z-cut is used, and accordingly, the direction perpendicular to the length direction of the electrode fingers 3 and the electrode fingers 4 is a direction perpendicular to a polarization direction of the piezoelectric layer 2. When a piezoelectric body that has another cut-angle is used as the piezoelectric layer 2, this is not the case. The meaning of “perpendicular” described herein is not limited only to the case of being strictly perpendicular but may be the meaning of substantially perpendicular (an angle between the direction perpendicular to the length direction of the electrode fingers 3 and the electrode fingers 4 and the polarization direction is, for example, about 90°±10°).

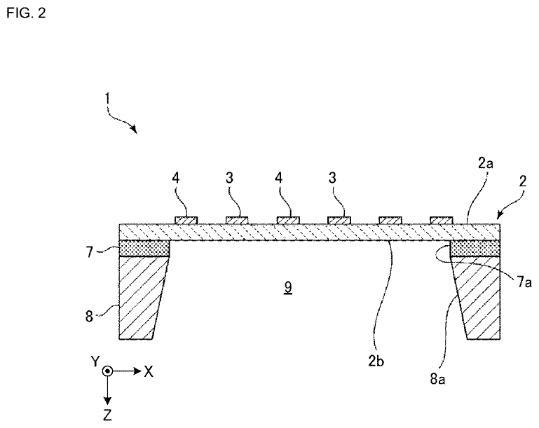

A support substrate 8 is stacked along the second main surface 2b of the piezoelectric layer 2 with an intermediate layer 7 interposed therebetween. As illustrated in FIG. 2, the intermediate layer 7 has a frame shape and has a cavity 7a, and the support substrate 8 has a frame shape and has a cavity 8a. Consequently, a hollow portion (an air gap) 9 is provided.

The hollow portion 9 is provided so as not to prevent an excitation region C of the piezoelectric layer 2 from vibrating. Accordingly, the support substrate 8 described above is stacked along the second main surface 2b with the intermediate layer 7 interposed therebetween at a position at which the support substrate 8 does not overlap a portion where at least one pair of the electrode finger 3 and the electrode finger 4 is provided. The intermediate layer 7 is not necessarily provided. Accordingly, the support substrate 8 can be stacked directly on or indirectly along the second main surface 2b of the piezoelectric layer 2.

The intermediate layer 7 is made of silicon oxide. The intermediate layer 7 can be made of an appropriate electrically insulating material, such as silicon nitride or alumina other than silicon oxide. The intermediate layer 7 described herein is an example of an “intermediate layer”.

The support substrate 8 is made of Si. A plane direction of a Si surface that faces the piezoelectric layer 2 may be (100) or (110) or may be (111). High-resistance Si having a resistivity of about 4 kΩ or higher is preferable, for example. The support substrate 8 can be made of an appropriate electrically insulating material or a semiconductor material. Examples of the material of the support substrate 8 can include a piezoelectric material, such as aluminum oxide, lithium tantalate, lithium niobate, and quartz crystal, various kinds of ceramics, such as alumina, magnesia, sapphire, silicon nitride, aluminum nitride, silicon carbide, zirconia, cordierite, mullite, steatite, and forsterite, a dielectric, such as diamond and glass, and a semiconductor, such as gallium nitride.

The multiple electrode fingers 3, the multiple electrode fingers 4, the first busbar electrode 5, and the second busbar electrode 6 described above are made of an appropriate metal or alloy, such as Al and an AlCu alloy. According to the present preferred embodiment, the electrode fingers 3, the electrode fingers 4, the first busbar electrode 5, and the second busbar electrode 6 have a structure in which an Al film is stacked on a Ti film. A close-contact layer other than a Ti film may be used.

At the time of driving, an alternating voltage is applied across the multiple electrode fingers 3 and the multiple electrode fingers 4. More specifically, an alternating voltage is applied across the first busbar electrode 5 and the second busbar electrode 6. Consequently, resonance characteristics can be obtained by using a bulk wave in the first thickness-shear mode that is excited in the piezoelectric layer 2.

As for the acoustic wave device 1, d/p is about 0.5 or less, for example, where d is the thickness of the piezoelectric layer 2, and p is the distance between the centers of one of the electrode fingers 3 and one of the electrode fingers 4 adjacent to each other among multiple pairs of the electrode fingers 3 and the electrode fingers 4. For this reason, a bulk wave in the first thickness-shear mode described above is effectively excited, and good resonance characteristics can be obtained. More preferably, d/p is about 0.24 or less, for example. In this case, better resonance characteristics can be obtained.

In the case where at least the number of the electrode fingers 3 or the number of the electrode fingers 4 is more than one as in the present preferred embodiment, that is, in the case where there are 1.5 pairs or more of the electrode fingers 3 and 4 when one of the electrode fingers 3 and one of the electrode fingers 4 adjacent to each other are regarded as being included in a paired electrode set, the distance p between the centers of the electrode finger 3 and the electrode finger 4 means the average distance of the distances between the centers of the electrode fingers 3 and 4 adjacent to each other.

The acoustic wave device 1 according to the present preferred embodiment has the structure described above and is unlikely to decrease a Q value even in the case where the number of pairs of the electrode fingers 3 and the electrode fingers 4 is reduced to reduce the size. The reason is that a propagation loss is small because of a resonator that needs no reflectors on both sides. The reason why no reflectors are needed as described above is because a bulk wave in the first thickness-shear mode is used.

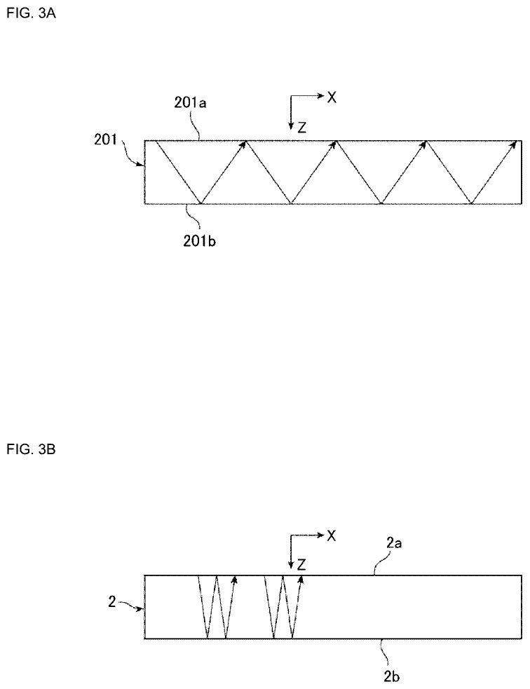

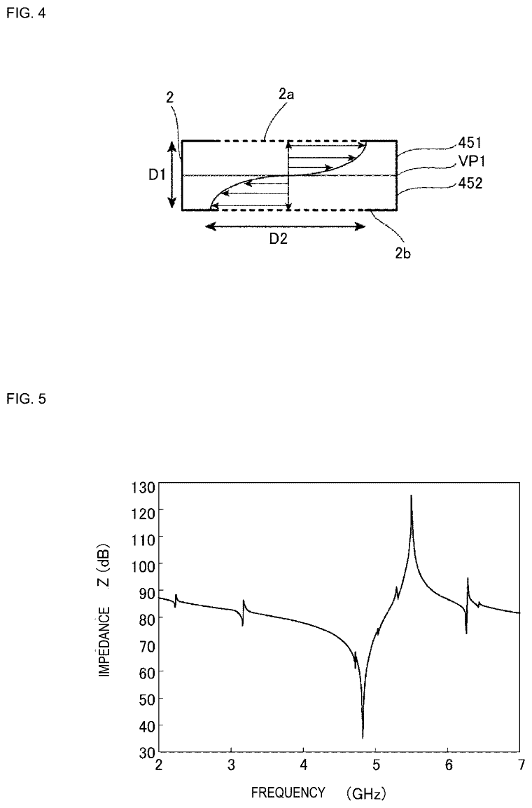

FIG. 3A is a sectional view for schematically illustrating a Lamb wave that propagates through a piezoelectric layer in a comparative example. FIG. 3B is a sectional view for schematically illustrating a bulk wave that propagates through the piezoelectric layer according to the present preferred embodiment in the first thickness-shear mode. FIG. 4 is a sectional view for schematically illustrating the amplitude direction of the bulk wave that propagates through the piezoelectric layer according to the present preferred embodiment in the first thickness-shear mode.

In FIG. 3A, a Lamb wave propagates through the piezoelectric layer of an acoustic wave device disclosed in Japanese Unexamined Patent Application Publication No. 2012-257019. As illustrated by using arrows in FIG. 3A, the wave propagates through a piezoelectric layer 201. The piezoelectric layer 201 includes a first main surface 201a and a second main surface 201b. A thickness direction in which the first main surface 201a and the second main surface 201b are connected is the Z-direction. The X-direction is a direction in which the electrode fingers 3 and 4 of the functional electrode 30 are arranged. As illustrated in FIG. 3A, for the Lamb wave, the wave propagates in the X-direction as illustrated. The wave is a plate wave, and accordingly, the piezoelectric layer 201 vibrates as a whole. Since the wave propagates in the X-direction, however, resonance characteristics are obtained by providing reflectors on both sides. For this reason, a wave propagation loss occurs, and the Q value decreases in the case where the size is reduced, that is, in the case where the number of pairs of the electrode fingers 3 and 4 is reduced.

As for the acoustic wave device according to the present preferred embodiment, as illustrated in FIG. 3B, a vibration displacement is caused in a thickness-shear direction, a wave propagates substantially in the direction in which the first main surface 2a and the second main surface 2b of the piezoelectric layer 2 are connected, that is, the Z-direction, and resonance occurs. That is, a component of the wave in the X-direction is significantly smaller than a component in the Z-direction. The resonance characteristics are obtained from the propagation of the wave in the Z-direction, and accordingly, no reflectors are needed. Accordingly, a propagation loss when a wave propagates to reflectors is not made. Accordingly, the Q value is unlikely to decrease even in the case where the number of pairs of electrode pairs including the electrode fingers 3 and the electrode fingers 4 is reduced to reduce the size.

As illustrated in FIG. 4, the amplitude direction of a bulk wave in the first thickness-shear mode in a first region 451 that is included in the excitation region C (see FIG. 1B) of the piezoelectric layer 2 is opposite that in a second region 452 that is included in the excitation region C. FIG. 4 schematically illustrates the bulk wave when a voltage is applied across the electrode fingers 3 and the electrode fingers 4 such that the electrode fingers 4 have a potential higher than that of the electrode fingers 3. The first region 451 is a region in the excitation region C between the first main surface 2a and a virtual plane VP1 that is perpendicular to the thickness direction of the piezoelectric layer 2 and that divides the piezoelectric layer 2 into two. The second region 452 is a region in the excitation region C between the virtual plane VP1 and the second main surface 2b.

The acoustic wave device 1 includes at least one electrode pair including the electrode finger 3 and the electrode finger 4 but does not intend to cause the wave to propagate in the X-direction, and accordingly, the number of pairs of the electrode pairs including the electrode fingers 3 and the electrode fingers 4 is not necessarily more than one. That is, at least one electrode pair suffices.

For example, the electrode fingers 3 described above correspond to electrodes that are connected to a hot potential, and the electrode fingers 4 correspond to electrodes that are connected to a ground potential. The electrode fingers 3 may be connected to the ground potential, and the electrode fingers 4 may be connected to the hot potential. According to the present preferred embodiment, an electrode of at least one electrode pair is an electrode that is connected to the hot potential or an electrode that is connected to the ground potential as described above, and no floating electrode is provided.

FIG. 5 is a graph illustrating an example of the resonance characteristics of the acoustic wave device according to the present preferred embodiment. Examples of the design parameters of the acoustic wave device 1 that obtains the resonance characteristics illustrated in FIG. 5 are as follows.

The piezoelectric layer 2 is made of LiNbO₃ where the Euler angles are (0°, 0°, 90°), and the piezoelectric layer 2 has a thickness of 400 nm.

The length of the excitation region C (see FIG. 1B) is 40 μm, the number of pairs of the electrodes including the electrode fingers 3 and the electrode fingers 4 is 21, the distance (the pitch) between the centers of the electrode finger 3 and the electrode finger 4 is 3 μm, the width of each of the electrode fingers 3 and the electrode fingers 4 is 500 nm, and d/p is 0.133.

The intermediate layer 7 is made of a silicon oxide film having a thickness of 1 μm.

The support substrate 8 is made of Si.

The excitation region C (see FIG. 1B) means an overlapping region in which the electrode fingers 3 overlap the electrode fingers 4 when viewed in the X-direction that intersects with the length direction of the electrode fingers 3 and the electrode fingers 4. The length of the excitation region C is the dimension of the excitation region C in the length direction of the electrode fingers 3 and the electrode fingers 4. The excitation region C described herein is an example of an “intersecting region”.

According to the present preferred embodiment, as for all of the multiple pairs, the distances between the electrodes of the electrode pairs including the electrode fingers 3 and the electrode fingers 4 have the same value. That is, the electrode fingers 3 and the electrode fingers 4 are disposed at the same pitch.

As is apparent from FIG. 5, good resonance characteristics that exhibit a fractional band width of about 12.5% are obtained although no reflectors are provided.

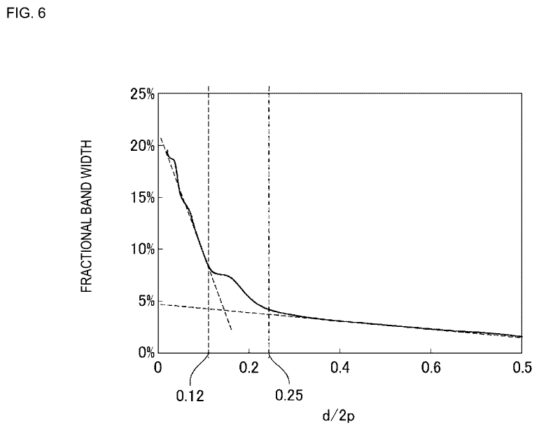

According to the present preferred embodiment, d/p is about 0.5 or less and preferably about 0.24 or less where d is the thickness of the piezoelectric layer 2 described above, and p is the distance between the centers of the electrodes of the electrode finger 3 and the electrode finger 4. This will be described with reference to FIG. 6.

Multiple acoustic wave devices are obtained in the same manner as the acoustic wave device that obtains the resonance characteristics illustrated in FIG. 5 although d/2p is changed. FIG. 6 is a graph illustrating the relationship between d/2p and the fractional band width of the acoustic wave device according to the present preferred embodiment that serves as a resonator where p is the distance between the centers of adjacent electrodes or the average distance of distances between the centers, and d is the average thickness of the piezoelectric layer 2.

As illustrated in FIG. 6, when d/2p exceeds about 0.25, that is, when d/p>about 0.5 is satisfied, the fractional band width is less than about 5% regardless of adjustment of d/p, for example. In contrast, when d/2p≤about 0.25 is satisfied, that is, when d/p≤about 0.5 is satisfied, the fractional band width can be about 5% or more, for example, that is, a resonator having a high coupling coefficient can be provided by changing d/p within the range. When d/2p is about 0.12 or less, that is, when d/p is about 0.24 or less, the fractional band width can be increased to about 7% or more, for example. In addition, a resonator having a greater fractional band width can be obtained, and a resonator having a higher coupling coefficient can be obtained by adjusting d/p within the range. Accordingly, it is understood that a resonator that uses a bulk wave in the first thickness-shear mode described above and that has a high coupling coefficient can be provided by setting d/p to about 0.5 or less, for example.

At least one electrode pair may be one electrode pair. In the case of one electrode pair, p described above is defined as the distance between the centers of the electrode finger 3 and the electrode finger 4 adjacent to each other. In the case of 1.5 or more electrode pairs, p is defined as the average distance of the distances between the centers of the electrode fingers 3 and 4 adjacent to each other.

When the piezoelectric layer 2 has thickness variations, an averaged thickness value is also used for the thickness d of the piezoelectric layer 2.

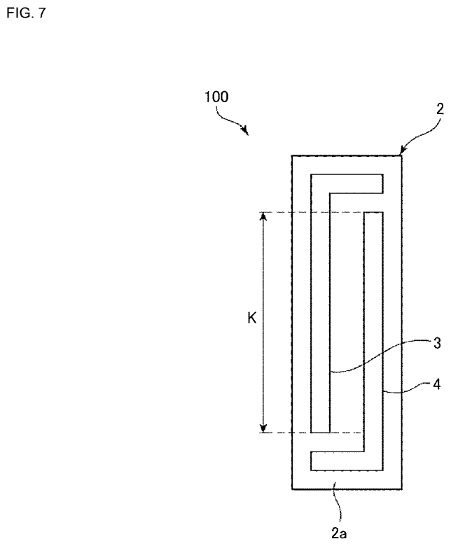

FIG. 7 is a plan view for illustrating an example in which the acoustic wave device according to the present preferred embodiment includes a pair of electrodes. In an acoustic wave device 101, one electrode pair including the electrode finger 3 and the electrode finger 4 is provided on the first main surface 2a of the piezoelectric layer 2. In FIG. 7, K is an intersecting width. As for the acoustic wave devices according to preferred embodiments of the present disclosure, the number of the pair of the electrodes may be one as described above. Also, in this case, when d/p described above is about 0.5 or less, for example, a bulk wave in the first thickness-shear mode can be effectively excited.

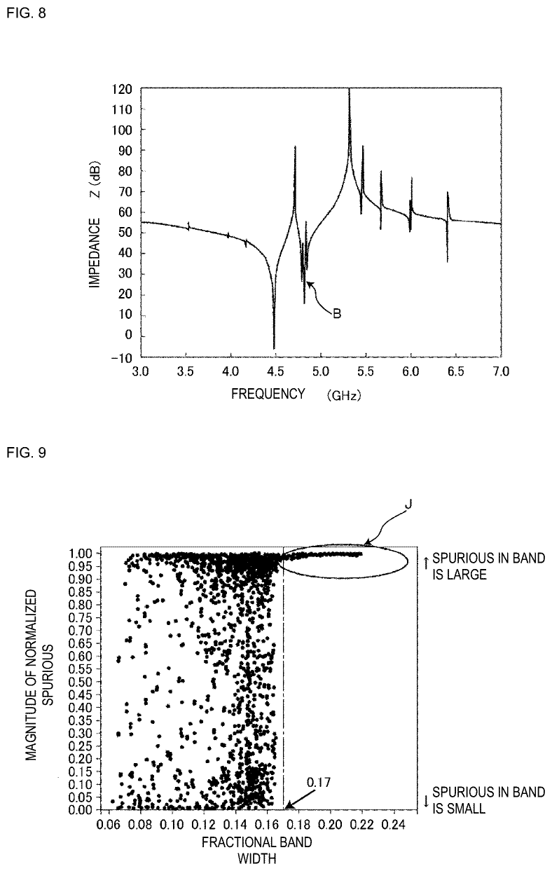

As for the acoustic wave device 1, with respect to the excitation region C that is a region in which the multiple electrode fingers 3 and the multiple electrode fingers 4 overlap when viewed in the direction in which one of the electrode fingers 3 and one of the electrode fingers 4 adjacent to each other face each other, a metallization ratio MR of the electrode finger 3 and the electrode finger 4 adjacent to each other as described above preferably satisfies MR≤about 1.75 (d/p)+0.075, for example. In this case, spurious can be effectively reduced. This will be described with reference to FIG. 8 and FIG. 9.

FIG. 8 is a reference graph illustrating an example of the resonance characteristics of the acoustic wave device according to the present preferred embodiment. The spurious illustrated by using an arrow B appears between a resonant frequency and an anti-resonant frequency. It is noted that d/p=about 0.08 is satisfied, and the Euler angles of LiNbO₃are (0°, 0°, 90°), for example. The metallization ratio described above satisfies MR=about 0.35, for example.

The metallization ratio MR will be described with reference to FIG. 1B. In the case where attention is paid to one pair of the electrode finger 3 and the electrode finger 4 in the electrode structure in FIG. 1B, it is assumed that only the one pair of the electrode finger 3 and the electrode finger 4 is provided. In this case, a portion surrounded by a one-dot chain line corresponds to the excitation region C. The excitation region C is a region of the electrode finger 3 that overlaps the electrode finger 4, a region of the electrode finger 4 that overlaps the electrode finger 3, and a region between the electrode finger 3 and the electrode finger 4 in which the electrode finger 3 and the electrode finger 4 overlap when the electrode finger 3 and the electrode finger 4 are viewed in the direction perpendicular to the length direction of the electrode finger 3 and the electrode finger 4, that is, the direction in which the electrode finger 3 and the electrode finger 4 face each other. The metallization ratio MR is obtained from the areas of the electrode finger 3 and the electrode finger 4 in the excitation region C with respect to the area of the excitation region C. That is, the metallization ratio MR is the ratio of the area of a metallization portion to the area of the excitation region C.

In the case where the multiple pairs of the electrode fingers 3 and the electrode fingers 4 are provided, MR is defined as the ratio of the metallization portions that are included in all of the excitation regions C to the total area of the excitation regions C.

FIG. 9 is a graph illustrating the relationship between the phase rotation amount of the impedance of spurious normalized at 180 degrees as the magnitude of the spurious and the fractional band width in the case where a large number of acoustic wave resonators of the acoustic wave device according to the present preferred embodiment are provided. The fractional band width is adjusted while the film thickness of the piezoelectric layer 2 and the dimensions of the electrode fingers 3 and the electrode fingers 4 are changed into various values. FIG. 9 illustrates a result in the case where the piezoelectric layer 2 is made of LiNbO₃ of Z-cut. A similar result is obtained also in the case where the piezoelectric layer 2 has another cut-angle.

In a region surrounded by an ellipse J in FIG. 9, the spurious is about 1.0 and large, for example. As is apparent from FIG. 9, when the fractional band width exceeds about 0.17, that is, about 17%, for example, large spurious having a spurious level of one or more appears in a pass band regardless of change in parameters on which the fractional band width depends. That is, large spurious illustrated by using the arrow B appears in the band as in the resonance characteristics illustrated in FIG. 8. Accordingly, the fractional band width is preferably about 17% or less, for example. In this case, the spurious can be reduced by adjusting, for example, the film thickness of the piezoelectric layer 2 and the dimensions of the electrode fingers 3 and the electrode fingers 4.

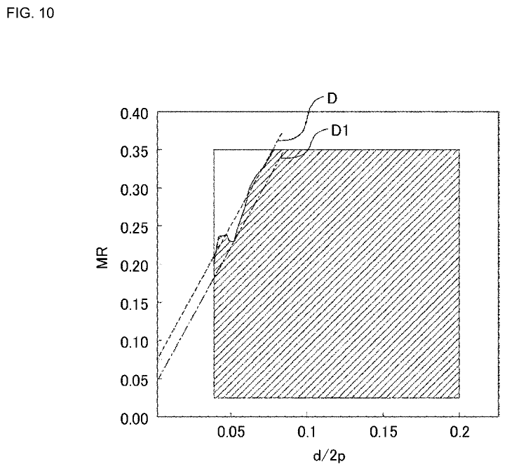

FIG. 10 is a graph illustrating the relationship among d/2p, the metallization ratio MR, and the fractional band width. Various acoustic wave devices 1 that have different values of d/2p and MR from those of the acoustic wave device 1 according to the present preferred embodiment are prepared, and the fractional band width is measured. A hatched portion on the right-hand side of a dashed line D in FIG. 10 corresponds to a region in which the fractional band width is about 17% or less, for example. The boundary between the hatched region and a non-hatched region is expressed as MR=about 3.5 (d/2p)+0.075, for example. That is, MR=about 1.75 (d/p)+0.075 is satisfied, for example. Accordingly, MR≤about 1.75 (d/p)+0.075 is preferably satisfied, for example. In this case, the fractional band width is likely to be about 17% or less, for example. A right-hand region illustrated by using a one-dot chain line D1 in FIG. 10 in which MR=about 3.5 (d/2p)+0.05 is satisfied is more preferable, for example. That is, when MR≤about 1.75 (d/p)+0.05 is satisfied, the fractional band width can be about 17% or less with certainty, for example.

FIG. 11 is a diagram illustrating a map of the fractional band width for the Euler angles (0°, θ, ψ) of LiNbO₃ when d/p is close to zero as much as possible. Hatched portions in FIG. 11 correspond to regions in which at least a fractional band width of about 5% or more is obtained, for example. The approximation of the ranges of the regions results in ranges that are expressed as the following expression (1), expression (2), and expression (3).

(0°±10°, 0° to 20°, freely selected ψ) (1)

(0°±10°, 20° to 80°, 0° to 60° (1−(θ−50)²/900)^{1/2}) or (0°±10°, 20° to 80°, [180°−60° (1−(θ−50)²/900)^{1/2}] to) 180°) (2)

(0°±10°, [180°−30° (1−(ψ−90)²/8100)^{1/2}] to 180°, freely selected ψ) (3)

Accordingly, in the case of the ranges of the Euler angles expressed as the expression (1), the expression (2), or the expression (3) described above, the fractional band width can be sufficiently increased, which is preferable.

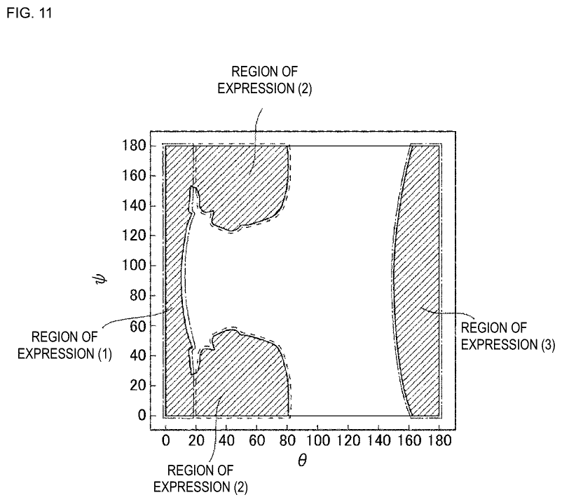

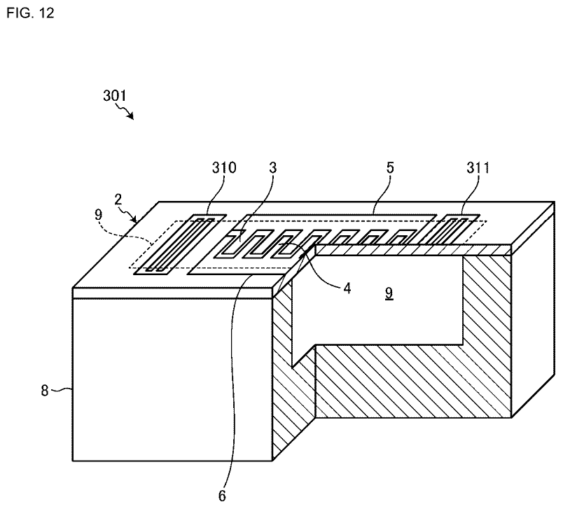

FIG. 12 is a perspective view of the acoustic wave device according to the present preferred embodiment from which a portion is cut. FIG. 12 illustrates an outer circumferential edge of the hollow portion 9 by using a dashed line. The acoustic wave devices according to preferred embodiments of the present disclosure may use a plate wave. In this case, as illustrated in FIG. 12, an acoustic wave device 301 includes reflectors 310 and 311. The reflectors 310 and 311 are provided in or on the piezoelectric layer 2 on both sides of the electrode fingers 3 and 4 in a direction in which an acoustic wave propagates. As for the acoustic wave device 301, an alternating electric field is applied to the electrode fingers 3 and 4 above the hollow portion 9, and consequently, a Lamb wave as a plate wave is excited. At this time, since the reflectors 310 and 311 are provided on both sides, resonance characteristics due to the Lamb wave as the plate wave can be obtained.

The acoustic wave devices 1 and 101 use a bulk wave in the first thickness-shear mode as described above. As for the acoustic wave devices 1 and 101, the electrode fingers 3 and the electrode fingers 4 correspond to adjacent electrodes, and d/p is about 0.5 or less, for example, where d is the thickness of the piezoelectric layer 2, and p is the distance between the centers of the electrode finger 3 and the electrode finger 4. This enables the Q value to be increased even in the case where the size of the acoustic wave device is reduced.

As for the acoustic wave devices 1 and 101, the piezoelectric layer 2 is made of lithium niobate or lithium tantalate. The electrode fingers 3 and the electrode fingers 4 that face each other in the direction that intersects with the thickness direction of the piezoelectric layer 2 are preferably in or on the first main surface 2a or the second main surface 2b of the piezoelectric layer 2, and a protection film preferably covers the electrode fingers 3 and the electrode fingers 4.

### First Preferred Embodiment

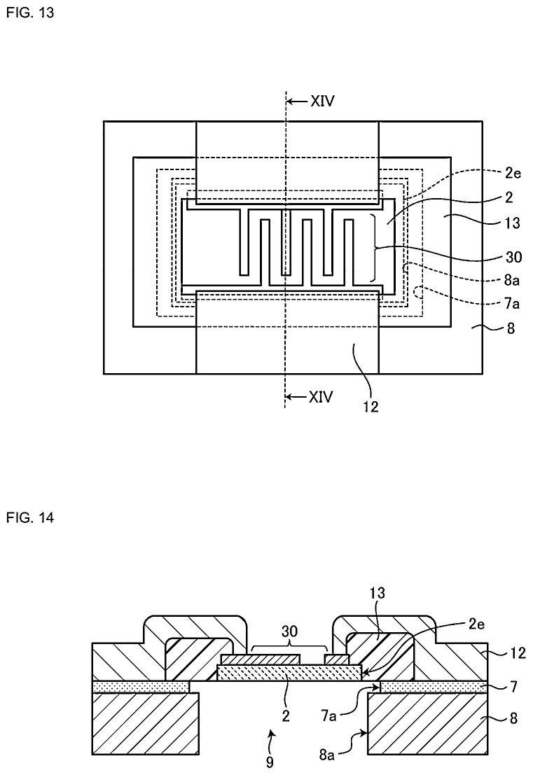

FIG. 13 is a plan view of an acoustic wave device according to a first preferred embodiment. FIG. 14 illustrates a section taken along line XIV-XIV in FIG. 13. In an example illustrated in FIG. 13, the first busbar electrode 5 and the second busbar electrode 6 in FIG. 12 are connected to a wiring electrode 12 that is provided along the first main surface 2a of the piezoelectric layer 2, but this is just an example.

As for the acoustic wave device according to the first preferred embodiment, as illustrated in FIG. 13 and FIG. 14, the hollow portion 9 is provided in a surface of the support substrate 8 that faces the piezoelectric layer 2 in the Z-direction. The hollow portion 9 is rectangular in a plan view in the Z-direction and is provided so as to at least partly overlap the functional electrode 30. As illustrated in FIG. 14, the hollow portion 9 is a space that is surrounded by the piezoelectric layer 2, the intermediate layer 7, and the support substrate 8. The intermediate layer 7 and the support substrate 8 have a frame shape and have the cavity 7a and the cavity 8a. An example of the support substrate 8 is a silicon substrate. The intermediate layer 7 is made of, for example, silicon oxide. The support substrate 8 and the intermediate layer 7 define and function as support members. For example, the piezoelectric layer includes lithium niobate or lithium tantalate. The piezoelectric layer 2 may include lithium niobate or lithium tantalate and inevitable impurities. The functional electrode 30 described herein is an interdigital transducer electrode that includes the first busbar electrode 5 and the second busbar electrode 6 that face each other, the electrode fingers 3 that are connected to the first busbar electrode 5, and the electrode fingers 4 that are connected to the second busbar electrode 6. According to the first preferred embodiment, the functional electrode 30 is provided in or on the first main surface 2a of the piezoelectric layer 2, but may be provided in or on the second main surface of the piezoelectric layer 2 opposite the first main surface 2a.

As illustrated in FIG. 13, the cavity 8a is inside the cavity 7a. An edge portion 2e of the piezoelectric layer 2 is inside the cavity 7a. A stress-relaxing layer 13 is between the edge portion 2e of the piezoelectric layer 2 and the cavity 7a of the intermediate layer 7, and the stress-relaxing layer 13 is stacked on the intermediate layer 7. The edge portion 2e of the piezoelectric layer 2 is entirely surrounded by the stress-relaxing layer 13. As illustrated in FIG. 13, the area of a portion (a membrane portion) of the piezoelectric layer 2 that overlaps the hollow portion 9 illustrated in FIG. 14 is smaller than the area of the cavity 7a of the intermediate layer 7. The wiring electrode 12 that is connected to the functional electrode is provided on the stress-relaxing layer 13. The stress-relaxing layer 13 is interposed between the wiring electrode 12 and the support substrate 8 (the intermediate layer 7 as the support member). The area of the stress-relaxing layer 13 is smaller than the area of the wiring electrode 12 when viewed in a direction in which the support substrate 8 and the piezoelectric layer 2 are stacked.

An example of the material of the stress-relaxing layer 13 is resin. The material of the stress-relaxing layer 13 may be metal such as Ti, Cu, Al, or Au or a multilayer body of metal and resin. The material of the stress-relaxing layer 13 may include impurities in addition to metal, resin, or a multilayer body of metal and resin. In the case where the stress-relaxing layer 13 is made of metal, the stress-relaxing layer 13 may define and function as a portion of the wiring electrode 12. The elastic modulus of the stress-relaxing layer 13 is preferably smaller than that of the intermediate layer 7 in order to reduce or prevent cracking of the piezoelectric layer 2. In the case of metal, however, the elastic modulus may be large because of ductility.

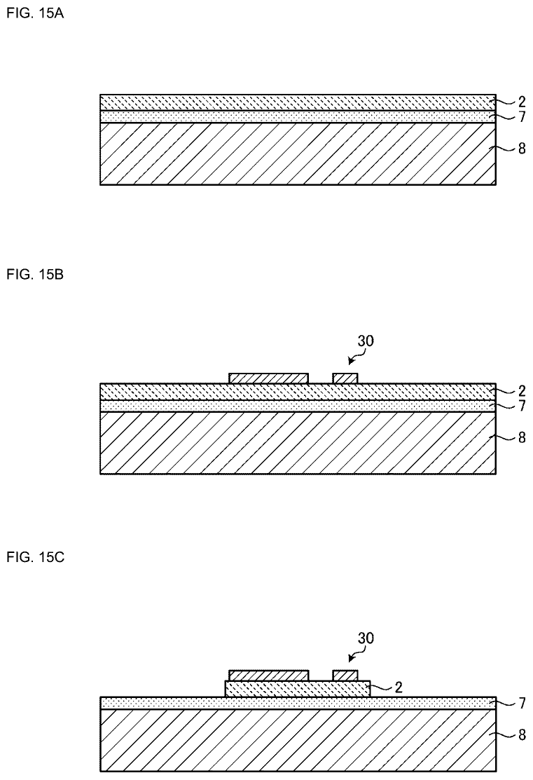

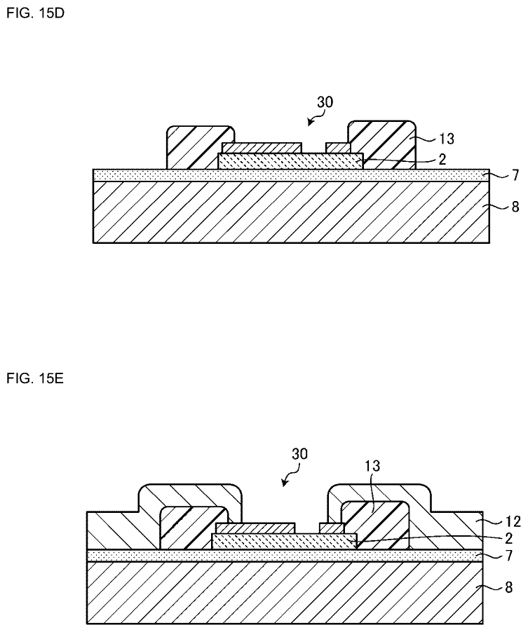

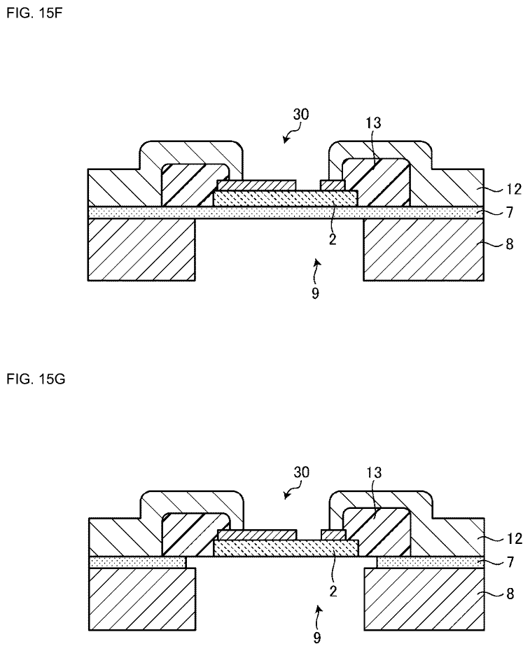

A non-limiting example of a method of manufacturing the acoustic wave device according to the first preferred embodiment will now be described with reference to FIGS. 15A to 15F.

FIG. 15A illustrates a joining step in the method of manufacturing the acoustic wave device according to the first preferred embodiment. As illustrated in FIG. 15A, the intermediate layer 7 is formed on the support substrate 8. The intermediate layer 7 can be made of an appropriate insulating material such as silicon oxide, silicon nitride, or alumina. The piezoelectric layer 2 is stacked on the intermediate layer 7, and a multilayer body is formed.

FIG. 15B illustrates an electrode forming step in the method of manufacturing the acoustic wave device according to the first preferred embodiment. Subsequently, as illustrated in FIG. 15B, the functional electrode 30 is formed by using, for example, a lift-off method.

FIG. 15C illustrates a piezoelectric layer etching step in the method of manufacturing the acoustic wave device according to the first preferred embodiment. Subsequently, a portion of the piezoelectric layer 2 is covered by a resist, the piezoelectric layer 2 is etched where no resist is formed, and consequently, the area of the piezoelectric layer 2 reduces as illustrated in FIG. 15C.

FIG. 15D illustrates a stress-relaxing layer forming step in the method of manufacturing the acoustic wave device according to the first preferred embodiment. Subsequently, as illustrated in FIG. 15D, the stress-relaxing layer 13 is formed on a portion of the periphery of the piezoelectric layer 2 and the intermediate layer 7 so as to surround the piezoelectric layer 2.

FIG. 15E illustrates a wiring electrode forming step in the method of manufacturing the acoustic wave device according to the first preferred embodiment. As illustrated in FIG. 15E, the wiring electrode 12 that is connected to the functional electrode 30 is provided on the stress-relaxing layer 13.

FIG. 15F illustrates a hollow forming step in the method of manufacturing the acoustic wave device according to the first preferred embodiment. As illustrated in FIG. 15F, a portion of the support substrate 8 is etched from a second main surface of the support substrate 8 opposite a first main surface along which the piezoelectric layer 2 is located. In the etching process, dry etching such as reactive ion etching is used. The hollow portion 9 extends through the support substrate 8, and a portion of the intermediate layer 7 is exposed.

FIG. 15G illustrates an intermediate layer etching step in the method of manufacturing the acoustic wave device according to the first preferred embodiment. As illustrated in FIG. 15G, a portion of the intermediate layer 7 is etched such that the piezoelectric layer 2 is exposed to the hollow portion 9. An example of etching for the intermediate layer 7 is wet etching. At this time, the hollow portion 9 extends through the support substrate 8, etchant for the intermediate layer 7 is accordingly easy to penetrate, and the state of the etching can be stable. The hollow portion 9 is formed such that an inner wall of the cavity 7a is separated from an inner wall of the cavity 8a. Consequently, the stress-relaxing layer 13 is exposed to the hollow portion 9. In the above manner, the acoustic wave device according to the first preferred embodiment is manufactured.

The method of manufacturing the acoustic wave device according to the first preferred embodiment thus includes the joining step, the electrode forming step, the piezoelectric layer etching step, the stress-relaxing layer forming step, and the hollow portion forming step. At the joining step, the support substrate 8 and the piezoelectric layer 2 are joined to each other with the intermediate layer 7 interposed therebetween. At the electrode forming step, the functional electrode 30 is formed in or on at least one of the main surfaces of the piezoelectric layer 2 after the joining step. At the piezoelectric layer etching step, an outer region of the piezoelectric layer 2 outside a region in which the functional electrode is formed is etched. At the stress-relaxing layer forming step, the stress-relaxing layer 13 is formed so as to at least partly overlap the piezoelectric layer 2 after the piezoelectric layer etching step. At the hollow portion forming step, the hollow portion 9 is formed such that the stress-relaxing layer 13 that is formed at the stress-relaxing layer forming step is exposed. Consequently, the stress-relaxing layer 13 that is softer than the support substrate 8 is interposed between the piezoelectric layer 2 and the support substrate 8, and accordingly, cracking of the piezoelectric layer 2 is reduced or prevented during manufacturing.

The acoustic wave device according to the first preferred embodiment includes the support substrate 8 that has the thickness in the first direction, the piezoelectric layer 2 that is provided in the first direction of the support substrate 8, and the functional electrode 30 that is provided in the first direction of the piezoelectric layer 2 as described above. The functional electrode 30 includes the multiple electrode fingers 3 that extend in the second direction perpendicular to the first direction and the multiple electrode fingers 4 that face any one of the multiple electrode fingers 3 in the third direction perpendicular to the first direction and the second direction and that extend in the second direction. The hollow portion 9 is provided between the support substrate 8 and the piezoelectric layer 2 in a plan view in the first direction at a position at which the hollow portion 9 at least partly overlaps the functional electrode 30. The stress-relaxing layer 13 overlaps an outer edge (the edge of the cavity 8a of the support substrate 8) of the hollow portion 9 in a plan view in the first direction. For this reason, the stress-relaxing layer 13 is interposed between the support substrate 8 and the piezoelectric layer 2.

Accordingly, the stress-relaxing layer 13 relieves stress between the support member and the piezoelectric layer 2, and cracking of the piezoelectric layer 2 is reduced or prevented.

In a preferred aspect of a preferred embodiment of the present invention, the elastic modulus of the stress-relaxing layer 13 is smaller than that of the intermediate layer 7. Consequently, the stress-relaxing layer 13 bends, and the stress between the support member and the piezoelectric layer 2 is easily relieved.

The piezoelectric layer 2 is smaller than an outer edge (the edge of the cavity 7a of the intermediate layer 7) of the hollow portion 9 in a plan view in the first direction. The stress-relaxing layer 13 surrounds the edge portion 2e of the piezoelectric layer 2. The stress-relaxing layer 13 overlaps the outer edge (the edge of the cavity 7a of the intermediate layer 7) of the hollow portion 9 in a plan view in the first direction. Consequently, the piezoelectric layer 2 is not in direct contact with the intermediate layer 7, and the piezoelectric layer 2 is unlikely to distort due to stress that is exerted from the intermediate layer 7.

In a preferred aspect of a preferred embodiment of the present invention, the thickness of the piezoelectric layer 2 is about 2p or less, for example, where p of the distance between the centers of one of the electrode fingers 3 and one of the electrode fingers 4 adjacent to each other among the multiple electrode fingers 3 and the multiple electrode fingers 4. This enables the size of the acoustic wave device 1 to be reduced and enables the Q value to be increased.

In a more preferred aspect of a preferred embodiment of the present invention, the piezoelectric layer 2 includes lithium niobate or lithium tantalate. This enables the acoustic wave device that obtains good resonance characteristics to be provided.

In a further preferred aspect of a preferred embodiment of the present invention, the Euler angles (φ, θ, ψ) of the lithium niobate or the lithium tantalate of which the piezoelectric layer 2 is made are within ranges of the expression (1), the expression (2) or the expression (3) described later. In this case, the fractional band width can be sufficiently increased.

(0°±10°, 0° to 20°, freely selected ψ) (1)

(0°±10°, 20° to 80°, 0° to 60° (1−(θ−50)²/900)^{1/2}) or (0°±10°, 20° to 80°, [180°−60° (1−(θ−50)²/900)^{1/2}] to) 180°) (2)

(0°±10°, [180°−30° (1−(ψ−90)²/8100)^{1/2}] to 180°, freely selected ψ) (3)

In a preferred aspect of a preferred embodiment of the present invention, as for the acoustic wave device 1, a bulk wave in a thickness-shear mode is usable. This enables the coupling coefficient to increase and enables the acoustic wave device that obtains good resonance characteristics to be provided.

In a more preferred aspect of a preferred embodiment of the present invention, d/p≤about 0.5 is satisfied, for example, where d is the thickness of the piezoelectric layer 2, and p is the distance between the centers of the electrode finger 3 and the electrode finger 4 adjacent to each other. This enables the size of the acoustic wave device 1 to be reduced and enables the Q value to be increased.

In a further preferred aspect of a preferred embodiment of the present invention, d/p is about 0.24 or less, for example. This enables the size of the acoustic wave device 1 to be reduced and enables the Q value to be increased.

In a preferred aspect of a preferred embodiment of the present invention, MR≤about 1.75 (d/p)+0.075 is satisfied, for example, where the overlapping region in the direction in which the electrode fingers 3 and the electrode fingers 4 adjacent to each other face each other is the excitation region C, and MR is the metallization ratio of the multiple electrode fingers 3 and the multiple electrode fingers 4 to the excitation region C. In this case, the fractional band width can be about 17% or less with certainty, for example.

In a preferred aspect of a preferred embodiment of the present invention, as for the acoustic wave device 301, a plate wave is usable. This enables the acoustic wave device that obtains good resonance characteristics to be provided.

### Second Preferred Embodiment

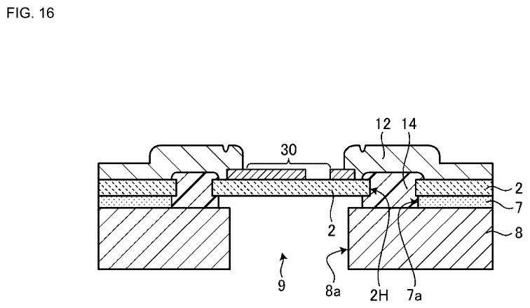

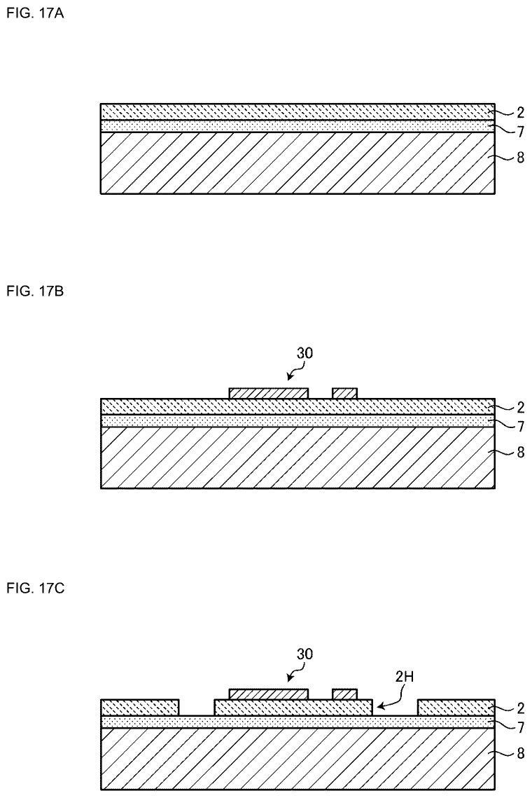

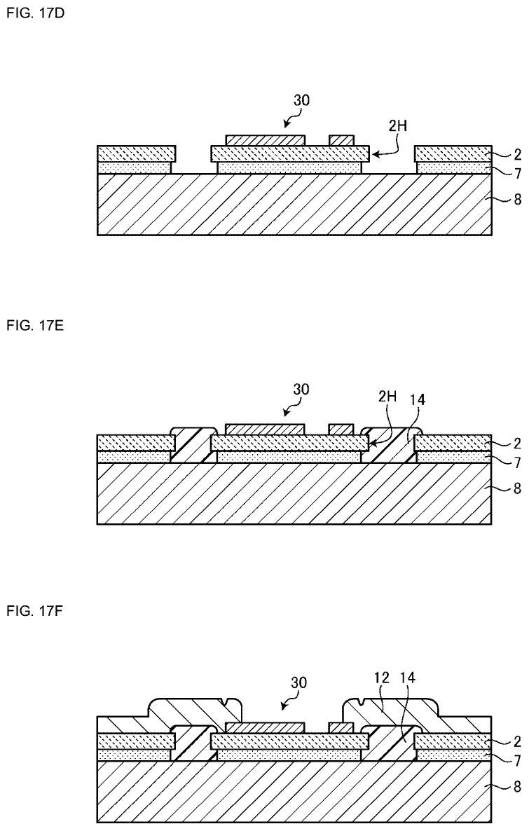

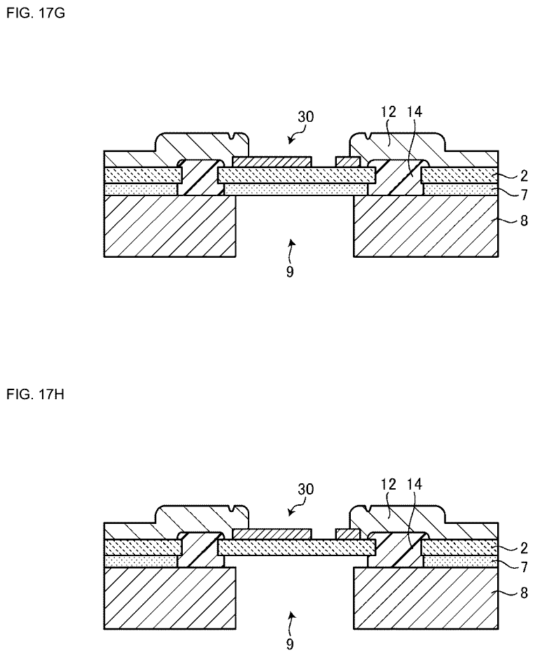

FIG. 16 illustrates an example of a section of an acoustic wave device according to the second preferred embodiment. The second preferred embodiment and a manufacturing method according to the second preferred embodiment will now be described with reference to FIG. 16, and FIGS. 17A to 17H.

As for the acoustic wave device according to the second preferred embodiment, a through-hole 2H that has a frame shape is provided in the piezoelectric layer 2, and the through-hole is filled with a stress-relaxing layer 14. Consequently, the stress-relaxing layer 14 is inside the cavity 7a of the intermediate layer 7. The stress-relaxing layer 14 is interposed between the wiring electrode 12 and the support substrate 8 (the support member). The piezoelectric layer 2 is larger than the outer edge (the edge of the cavity 8a of the support substrate 8) of the hollow portion 9.

FIG. 17A illustrates a joining step in a method of manufacturing the acoustic wave device according to the second preferred embodiment. As illustrated in FIG. 17A, the intermediate layer 7 is formed on the support substrate 8. The intermediate layer 7 can be made of an appropriate insulating material such as silicon oxide, silicon nitride, or alumina. The piezoelectric layer 2 is stacked on the intermediate layer 7, and a multilayer body is formed.

FIG. 17B illustrates an electrode forming step in the method of manufacturing the acoustic wave device according to the second preferred embodiment. Subsequently, as illustrated in FIG. 17B, the functional electrode 30 is formed by using, for example, a lift-off method.

FIG. 17C illustrates a piezoelectric layer etching step in the method of manufacturing the acoustic wave device according to the second preferred embodiment. Subsequently, a portion of the piezoelectric layer 2 is covered by a resist, the piezoelectric layer 2 is etched where no resist is formed, and consequently, the through-hole 2H of the piezoelectric layer 2 is formed as illustrated in FIG. 17C. The through-hole 2H has a rectangular or substantially rectangular frame shape.

FIG. 17D illustrates an intermediate layer first etching step in the method of manufacturing the acoustic wave device according to the second preferred embodiment. An example of first etching for the intermediate layer 7 is wet etching. At this time, etchant for the intermediate layer 7 is easy to penetrate the intermediate layer 7 via the through-hole 2H, and a portion of the intermediate layer 7 that overlaps the through-hole 2H is removed.

FIG. 17E illustrates a stress-relaxing layer forming step in the method of manufacturing the acoustic wave device according to the second preferred embodiment. Subsequently, as illustrated in FIG. 17E, the stress-relaxing layer 14 is formed on a portion of the periphery of the piezoelectric layer 2 and above the through-hole 2H so as to surround an inner portion of the piezoelectric layer 2 along the through-hole 2H. The through-hole 2H and a portion that is removed from the intermediate layer 7 are filled with the stress-relaxing layer 14.

FIG. 17F illustrates a wiring electrode forming step in the method of manufacturing the acoustic wave device according to the second preferred embodiment. As illustrated in FIG. 17F, the wiring electrode 12 that is connected to the functional electrode 30 is provided on the stress-relaxing layer 14.

FIG. 17G illustrates a hollow forming step in the method of manufacturing the acoustic wave device according to the second preferred embodiment. As illustrated in FIG. 17G, a portion of the support substrate 8 is etched from the second main surface of the support substrate 8 opposite the first main surface along which the piezoelectric layer 2 is located. In the etching process, dry etching such as reactive ion etching is used. The hollow portion 9 extends through the support substrate 8, and a portion of the intermediate layer 7 is exposed.

FIG. 17H illustrates an intermediate layer second etching step in the method of manufacturing the acoustic wave device according to the second preferred embodiment. As illustrated in FIG. 17H, a portion of the intermediate layer 7 is etched such that the piezoelectric layer 2 is exposed to the hollow portion 9. An example of second etching for the intermediate layer 7 is wet etching. At this time, the hollow portion 9 extends through the support substrate 8, etchant for the intermediate layer 7 is accordingly easy to penetrate the intermediate layer 7, and the state of the etching can be stable. The intermediate layer 7 that overlaps a portion (a membrane portion) of the piezoelectric layer 2 that overlaps the functional electrode 30 is removed, and the stress-relaxing layer 14 is exposed to the hollow portion 9. In the above manner, the acoustic wave device according to the second preferred embodiment is manufactured.

The method of manufacturing the acoustic wave device thus includes the joining step, the electrode forming step, the piezoelectric layer etching step, the intermediate layer first etching step, the stress-relaxing layer forming step, and the hollow portion forming step. At the joining step, the support substrate 8 and the piezoelectric layer 2 are joined to each other with the intermediate layer 7 interposed therebetween. At the electrode forming step, the functional electrode 30 is formed in or on at least one of the main surfaces of the piezoelectric layer 2 after the joining step. At the piezoelectric layer etching step, an outer region of the piezoelectric layer 2 outside a region in which the functional electrode is formed is etched into a frame shape, and the through-hole 2H is formed. At the stress-relaxing layer forming step, the stress-relaxing layer 14 is formed so as to overlap the through-hole 2H. At the hollow portion forming step, the hollow portion 9 is formed such that the stress-relaxing layer 14 that is formed at the stress-relaxing layer forming step is exposed. Consequently, the stress-relaxing layer 14 that is softer than the support substrate 8 is interposed between the piezoelectric layer 2 and the support substrate 8, and accordingly, cracking of the piezoelectric layer 2 is reduced or prevented during manufacturing.

The acoustic wave device according to the second preferred embodiment includes the support substrate 8 that has the thickness in the first direction, the piezoelectric layer 2 that is provided in the first direction of the support substrate 8, and the functional electrode 30 that is provided in the first direction of the piezoelectric layer 2 as described above. The functional electrode 30 includes the multiple electrode fingers 3 that extend in the second direction perpendicular to the first direction and the multiple electrode fingers 4 that face any one of the multiple electrode fingers 3 in the third direction perpendicular to the first direction and the second direction and that extend in the second direction. The hollow portion 9 is provided between the support substrate 8 and the piezoelectric layer 2 in a plan view in the first direction at a position at which the hollow portion 9 at least partly overlaps the functional electrode 30. The through-hole 2H that extends through the piezoelectric layer 2 is provided, and the through-hole 2H is filled with the stress-relaxing layer 14. For this reason, the stress-relaxing layer 14 is disposed outside at least a portion of the outer edge (the edge of the cavity 8a of the support substrate 8) of the hollow portion 9 in a plan view in the first direction. The stress-relaxing layer 14 is interposed between the support substrate 8 and the piezoelectric layer 2.

Accordingly, the stress-relaxing layer 14 relieves the stress between the support member and the piezoelectric layer 2, and cracking of the piezoelectric layer 2 is reduced or prevented.

In a preferred aspect of a preferred embodiment of the present invention, the stress-relaxing layer 14 surrounds the hollow portion 9, the inner portion of the piezoelectric layer 2 at which the functional electrode 30 is formed is supported by the support substrate 8 with the stress-relaxing layer 14 interposed therebetween. The stress-relaxing layer 14 relieves the stress between the support substrate 8 and the piezoelectric layer 2, and cracking of the piezoelectric layer 2 is reduced or prevented.

### Third Preferred Embodiment

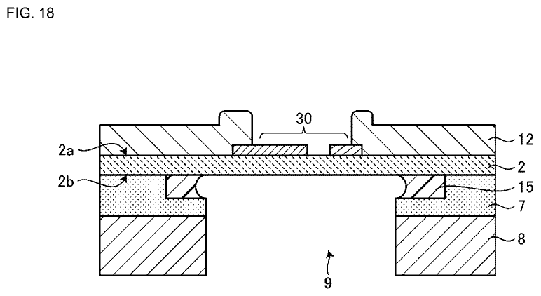

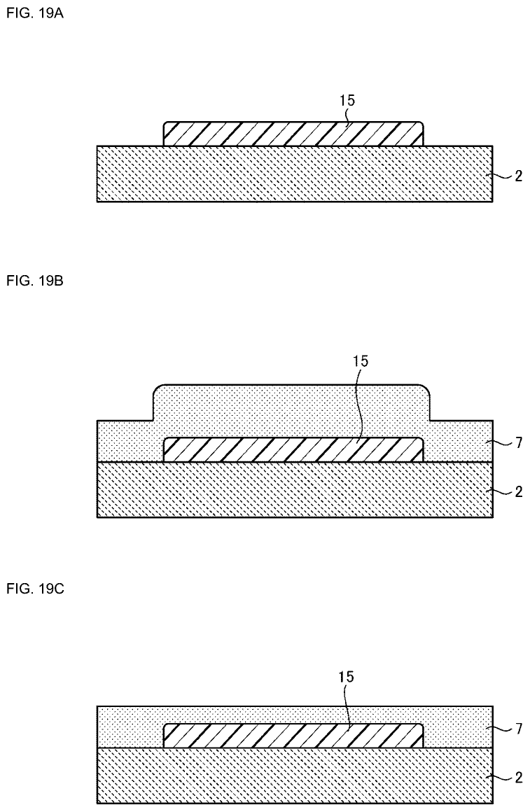

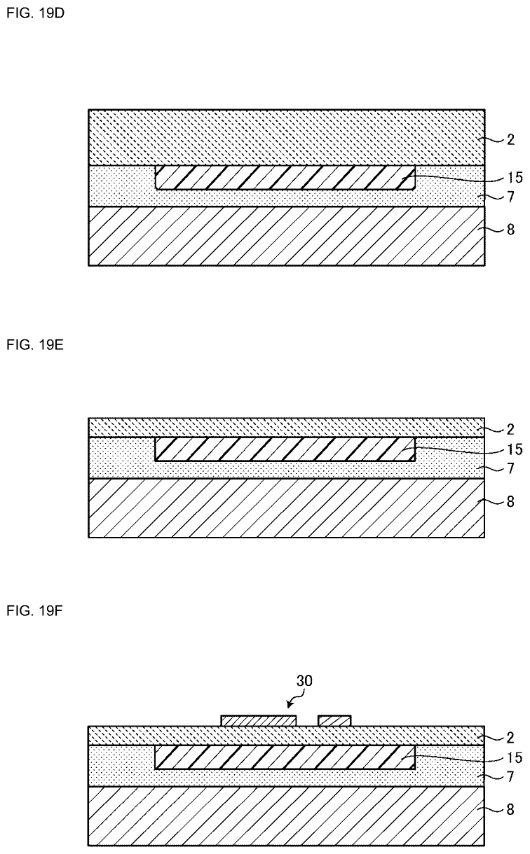

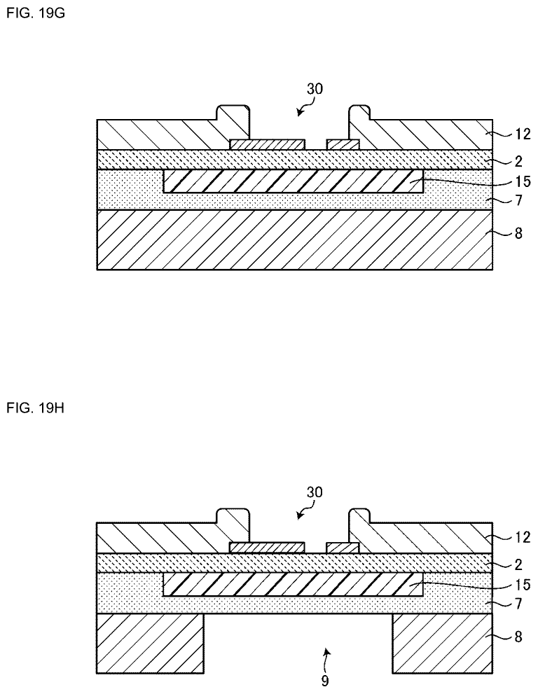

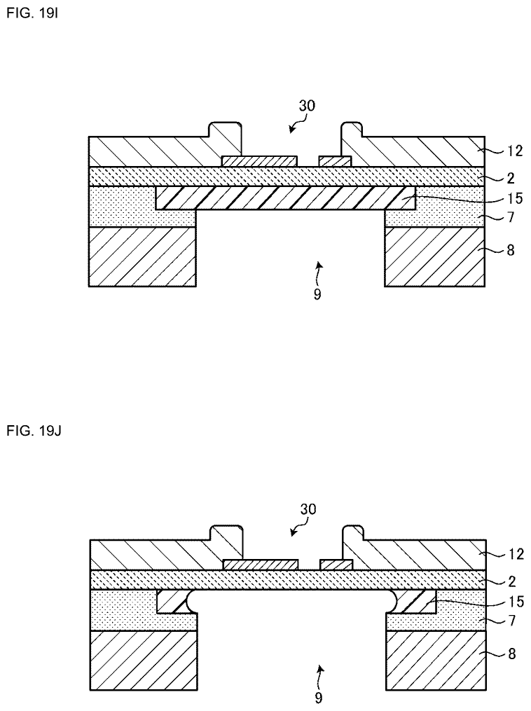

FIG. 18 illustrates an example of a section of an acoustic wave device according to a third preferred embodiment. The third preferred embodiment and a manufacturing method according to the third preferred embodiment will now be described with reference to FIG. 18, and FIGS. 19A to 19I.

A stress-relaxing layer 15 according to the third preferred embodiment faces the second main surface 2b of the piezoelectric layer 2. The stress-relaxing layer 15 is embedded in the intermediate layer 7. The stress-relaxing layer 15 is interposed between the wiring electrode 12 and the support substrate 8 (the intermediate layer 7 as the support member). The piezoelectric layer 2 is larger than the outer edge (the edge of the cavity 8a of the support substrate 8) of the hollow portion 9.

FIG. 19A illustrates a stress-relaxing layer forming step in a method of manufacturing the acoustic wave device according to the third preferred embodiment. As illustrated in FIG. 19A, the stress-relaxing layer 15 is formed on a portion of the second main surface 2b of the piezoelectric layer 2.

FIG. 19B illustrates an intermediate layer forming step in the method of manufacturing the acoustic wave device according to the third preferred embodiment. As illustrated in FIG. 19B, the intermediate layer 7 is formed so as to cover the piezoelectric layer 2 and the stress-relaxing layer 15. The intermediate layer 7 can be made of an appropriate insulating material such as silicon oxide, silicon nitride, or alumina.

FIG. 19C illustrates an intermediate layer flattening step in the method of manufacturing the acoustic wave device according to the third preferred embodiment. The intermediate layer 7 has unevenness caused by the stress-relaxing layer 15, and accordingly, the surface is flattened by, for example, chemical mechanical polishing.

FIG. 19D illustrates a joining step in the method of manufacturing the acoustic wave device according to the third preferred embodiment. As illustrated in FIG. 19D, the piezoelectric layer 2 is stacked on the intermediate layer 7, and a multilayer body is formed.

FIG. 19E illustrates a piezoelectric layer thinning step in the method of manufacturing the acoustic wave device according to the third preferred embodiment. As illustrated in FIG. 19E, the thickness of the piezoelectric layer 2 is reduced by, for example, chemical mechanical polishing.

FIG. 19F illustrates an electrode forming step in the method of manufacturing the acoustic wave device according to the third preferred embodiment. Subsequently, as illustrated in FIG. 19F, the functional electrode 30 is formed by using, for example, a lift-off method.

FIG. 19G illustrates a wiring electrode forming step in the method of manufacturing the acoustic wave device according to the third preferred embodiment. As illustrated in FIG. 19G, the wiring electrode 12 that is connected to the functional electrode 30 is provided above the stress-relaxing layer 15.

FIG. 19H illustrates a hollow forming step in the method of manufacturing the acoustic wave device according to the third preferred embodiment. As illustrated in FIG. 19H, a portion of the support substrate 8 is etched from the second main surface of the support substrate 8 opposite the first main surface along which the piezoelectric layer 2 is located. In the etching process, dry etching such as reactive ion etching is used. The hollow portion 9 extends through the support substrate 8, and a portion of the intermediate layer 7 is exposed.

FIG. 19I illustrates an intermediate layer etching step in the method of manufacturing the acoustic wave device according to the third preferred embodiment. As illustrated in FIG. 19I, a portion of the intermediate layer 7 is etched such that the stress-relaxing layer 15 is exposed to the hollow portion 9. An example of etching for the intermediate layer 7 is wet etching. At this time, the hollow portion 9 extends through the support substrate 8, etchant for the intermediate layer 7 is accordingly easy to penetrate the intermediate layer 7, and the state of the etching can be stable. The intermediate layer 7 that overlaps a portion (a membrane portion) of the piezoelectric layer 2 that overlaps the functional electrode 30 is removed, and the stress-relaxing layer 15 is exposed to the hollow portion 9.

FIG. 19J illustrates a stress-relaxing layer portion removing step in the method of manufacturing the acoustic wave device according to the third preferred embodiment. As illustrated in FIG. 19J, a portion of the stress-relaxing layer 15 is etched such that the piezoelectric layer 2 is exposed to the hollow portion 9. An example of etching for the stress-relaxing layer 15 is dry etching with chlorine gas when the stress-relaxing layer 15 is made of Ti. The stress-relaxing layer 15 that overlaps the portion (the membrane portion) of the piezoelectric layer 2 that overlaps the functional electrode 30 is removed, and the piezoelectric layer 2 is exposed to the hollow portion 9. In the above manner, the acoustic wave device according to the third preferred embodiment is manufactured.

The method of manufacturing the acoustic wave device according to the third preferred embodiment thus includes the stress-relaxing layer forming step, the intermediate layer forming step, the joining step, the piezoelectric layer thinning step, the electrode forming step, the hollow portion forming step, the intermediate layer etching step, and the stress-relaxing layer portion removing step. At the stress-relaxing layer forming step, the stress-relaxing layer 15 is formed on the second main surface 2b of the piezoelectric layer 2. Accordingly, the stress-relaxing layer 15 is formed on the piezoelectric layer 2 in advance, and the stress-relaxing layer 15 is embedded in the intermediate layer 7 at the intermediate layer forming step. For this reason, at the joining step, the piezoelectric layer 2 is joined to the support substrate 8 with the intermediate layer 7 interposed therebetween, and consequently, the stress-relaxing layer 15 is sandwiched between the piezoelectric layer 2 and the support substrate 8. The piezoelectric layer 2 is unlikely to crack even in the case where the piezoelectric layer thinning step is subsequently performed.

At the hollow portion forming step and the intermediate layer etching step, the hollow portion 9 is mostly formed, but according to the third preferred embodiment, the piezoelectric layer 2 is not exposed at this time. For this reason, at the stress-relaxing layer portion removing step, the piezoelectric layer 2 is exposed. The piezoelectric layer 2 is likely to crack at an edge of the hollow portion 9. According to the third preferred embodiment, however, the edge of the hollow portion 9 is surrounded by the stress-relaxing layer 15. Consequently, the stress-relaxing layer 15 that is softer than the support substrate 8 is interposed between the piezoelectric layer 2 and the support substrate 8, and accordingly, cracking of the piezoelectric layer 2 is reduced or prevented during manufacturing.

The acoustic wave device according to the third preferred embodiment includes the support substrate 8 that has the thickness in the first direction, the piezoelectric layer 2 that is provided in the first direction of the support substrate 8, and the functional electrode 30 that is provided in the first direction of the piezoelectric layer 2 as described above. The functional electrode 30 includes the multiple electrode fingers 3 that extend in the second direction perpendicular to the first direction and the multiple electrode fingers 4 that face any one of the multiple electrode fingers 3 in the third direction perpendicular to the first direction and the second direction and that extend in the second direction. The hollow portion 9 is provided between the support substrate 8 and the piezoelectric layer 2 in a plan view in the first direction at a position at which the hollow portion 9 at least partly overlaps the functional electrode 30. The stress-relaxing layer 15 is filled in the intermediate layer 7. For this reason, the stress-relaxing layer 15 is disposed outside at least a portion of the outer edge (the edge of the cavity 8a of the support substrate 8) of the hollow portion 9 in a plan view in the first direction. The stress-relaxing layer 15 is interposed between the support substrate 8 and the piezoelectric layer 2 at the edge of the hollow portion 9.

Accordingly, the stress-relaxing layer 15 relieves the stress between the support member and the piezoelectric layer 2, and cracking of the piezoelectric layer 2 is reduced or prevented.

### Fourth Preferred Embodiment

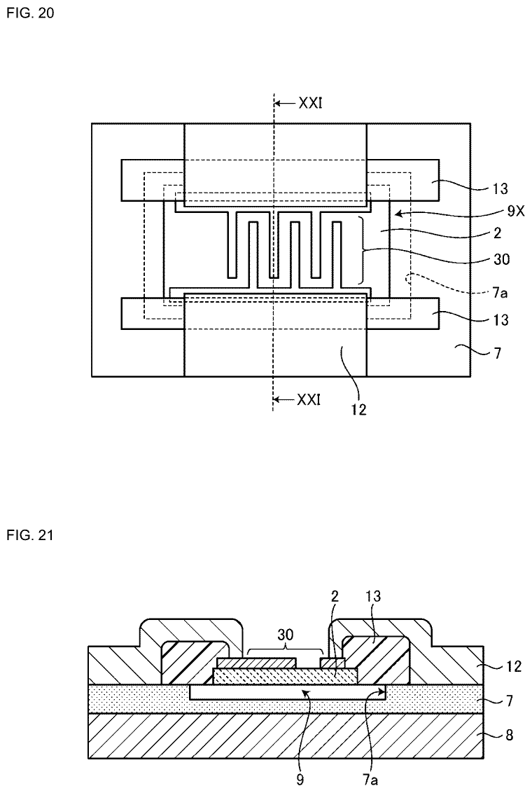

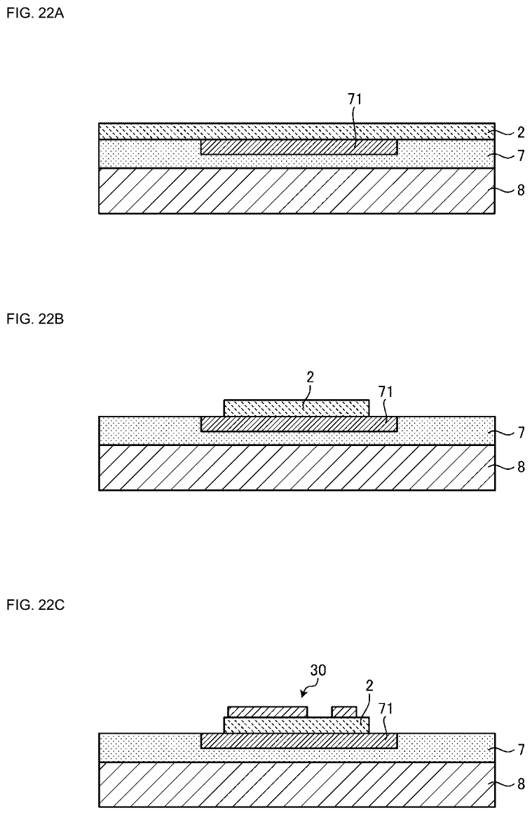

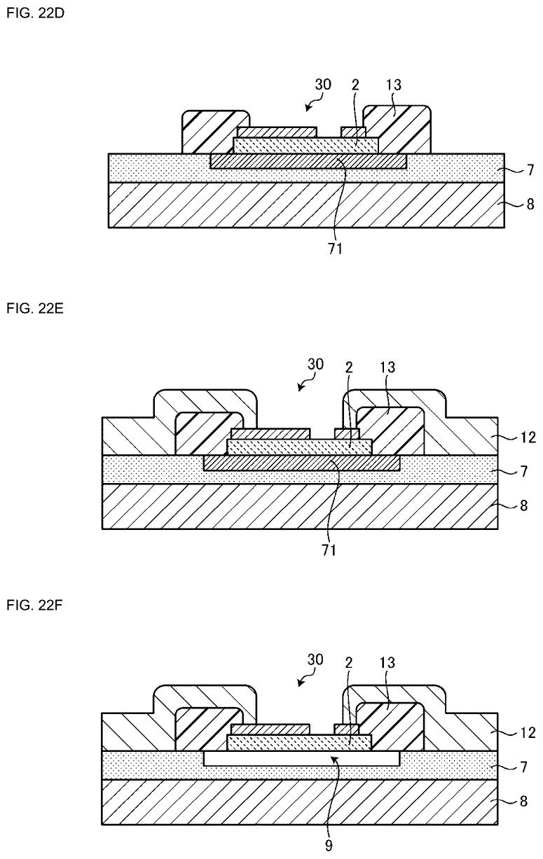

FIG. 20 is a plan view of an acoustic wave device according to a fourth preferred embodiment. FIG. 21 illustrates a section taken along line XXI-XXI in FIG. 20. The fourth preferred embodiment and a manufacturing method according to the fourth preferred embodiment will now be described with reference to FIG. 20, FIG. 21, and FIGS. 22A to 22F.

As for the acoustic wave device according to the fourth preferred embodiment, the hollow portion 9 is provided in the intermediate layer 7. A recessed portion of the intermediate layer 7 corresponds to the hollow portion 9. In a plan view in the first direction, the outer edge (the edge of the cavity 7a of the intermediate layer 7) of the hollow portion 9 is rectangular or substantially rectangular, and the stress-relaxing layers 13 cover two sides of the outer edge (the edge of the cavity 7a of the intermediate layer 7) of the hollow portion 9. The stress-relaxing layers 13 are interposed between the wiring electrode 12 and the support substrate 8 (the intermediate layer 7 of the support member).

The piezoelectric layer 2 is smaller than the outer edge (the edge of the cavity 7a of the intermediate layer 7) of the hollow portion 9. The stress-relaxing layers 13 cover the two sides of the outer edge (the edge of the cavity 7a of the intermediate layer 7) of the hollow portion 9. Two holes 9X that are in communication with the hollow portion 9 are exposed to two sides of the outer edge (the edge of the cavity 7a of the intermediate layer 7) of the hollow portion 9 that are not covered by the stress-relaxing layers 13.

FIG. 22A illustrates a joining step in a method of manufacturing the acoustic wave device according to the fourth preferred embodiment. As illustrated in FIG. 22A, the intermediate layer 7 is formed on the support substrate 8. The intermediate layer 7 can be made of an appropriate insulating material such as silicon oxide, silicon nitride, or alumina. A sacrificial layer 71 is embedded in the intermediate layer 7. A material that is more likely to be dissolved in an etching solution than the material of the intermediate layer 7 is used for the sacrificial layer 71. Subsequently, the piezoelectric layer 2 is stacked on the intermediate layer 7 and the sacrificial layer 71, and a multilayer body is formed.

FIG. 22B illustrates a piezoelectric layer etching step in the method of manufacturing the acoustic wave device according to the fourth preferred embodiment. Subsequently, a portion of the piezoelectric layer 2 is covered by a resist, the piezoelectric layer 2 is etched where no resist is formed, and consequently, the sacrificial layer 71 is exposed outside the piezoelectric layer 2 as illustrated in FIG. 22B. As for the sacrificial layer 71, a rectangular or substantially rectangular frame shape surrounds the periphery of the piezoelectric layer 2.

FIG. 22C illustrates an electrode forming step in the method of manufacturing the acoustic wave device according to the fourth preferred embodiment. Subsequently, as illustrated in FIG. 22C, the functional electrode 30 is formed by using, for example, a lift-off method.

FIG. 22D illustrates a stress-relaxing layer forming step in the method of manufacturing the acoustic wave device according to the fourth preferred embodiment. Subsequently, as illustrated in FIG. 22D, the stress-relaxing layers 13 are formed on portions of the periphery of the piezoelectric layer 2, the sacrificial layer 71, and the intermediate layer 7. As illustrated in FIG. 20, the stress-relaxing layers 13 are provided along two sides that face each other in the length direction (the Y-direction or the second direction) of the electrode fingers. Consequently, a portion of the sacrificial layer 71 is not covered by the stress-relaxing layers 13.

FIG. 22E illustrates a wiring electrode forming step in the method of manufacturing the acoustic wave device according to the fourth preferred embodiment. As illustrated in FIG. 20, FIG. 21, and FIG. 22E, the wiring electrode 12 that is connected to the functional electrode 30 is provided on the stress-relaxing layers 13.

FIG. 22F illustrates a sacrificial layer etching step in the method of manufacturing the acoustic wave device according to the fourth preferred embodiment. As illustrated in FIG. 20, the sacrificial layer 71 is etched from a position that faces the first main surface of the support substrate 8 along which the piezoelectric layer 2 is located, the holes 9X are consequently formed, and the etching solution removes the sacrificial layer 71. In the etching process, wet etching is used. As illustrated in FIG. 22F, the hollow portion 9 is formed at which the sacrificial layer 71 is removed and is surrounded by the intermediate layer 7. The sacrificial layer etching step is thus a hollow forming step.

The method of manufacturing the acoustic wave device according to the fourth preferred embodiment includes at least the joining step, the electrode forming step, the piezoelectric layer etching step, the stress-relaxing layer forming step, and the hollow portion forming step. According to the fourth preferred embodiment, at the joining step, the support substrate 8 and the piezoelectric layer 2 sandwich the intermediate layer that partly includes the sacrificial layer 71 therebetween so as to be stacked into one piece and are joined to each other. At the hollow portion forming step, the sacrificial layer 71 is etched, and consequently, the hollow portion 9 the outer edge of which is larger than the piezoelectric layer 2 in a plan view in the first direction is formed.

The acoustic wave device according to the fourth preferred embodiment includes the support substrate 8 that has the thickness in the first direction, the piezoelectric layer 2 that is provided in the first direction of the support substrate 8, and the functional electrode 30 that is provided in the first direction of the piezoelectric layer 2 as described above. The functional electrode 30 includes the multiple electrode fingers 3 that extend in the second direction perpendicular to the first direction and the multiple electrode fingers 4 that face any one of the multiple electrode fingers 3 in the third direction perpendicular to the first direction and the second direction and that extend in the second direction. The hollow portion 9 is provided between the support substrate 8 and the piezoelectric layer 2 in a plan view in the first direction at a position at which the hollow portion 9 at least partly overlaps the functional electrode 30. As illustrated in FIG. 20, the stress-relaxing layers 13 overlap the outer edge (the edge of the cavity 7a of the intermediate layer 7) of the hollow portion 9 in a plan view in the first direction. For this reason, the stress-relaxing layers 13 are interposed between the support substrate 8 and the piezoelectric layer 2.

Accordingly, the stress-relaxing layers 13 relieve the stress between the support member and the piezoelectric layer 2, and cracking of the piezoelectric layer 2 is reduced or prevented.

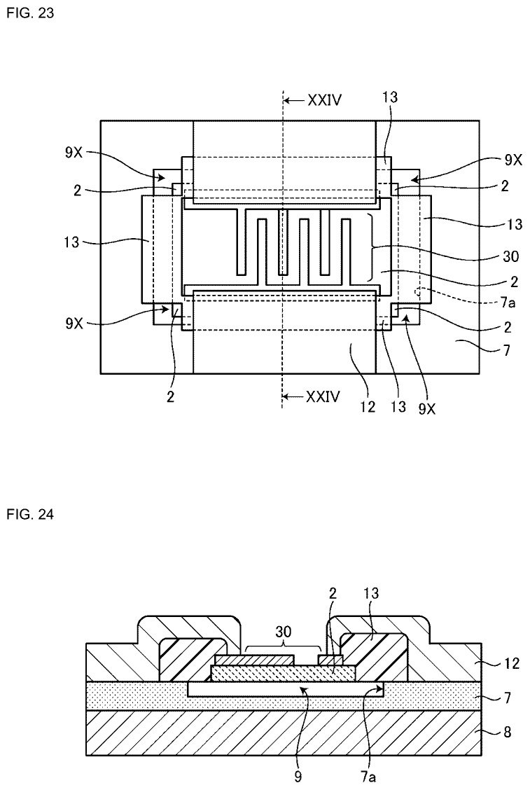

FIG. 23 is a plan view of an acoustic wave device according to a modification to the fourth preferred embodiment. FIG. 24 illustrates a section taken along line XXIV-XXIV in FIG. 23. As for the acoustic wave device according to the modification to the fourth preferred embodiment, the hollow portion 9 is provided in the intermediate layer 7. A recessed portion of the intermediate layer 7 corresponds to the hollow portion 9. The outer edge (the edge of the cavity 7a of the intermediate layer 7) of the hollow portion 9 is rectangular or substantially rectangular in a plan view in the first direction, and the stress-relaxing layers 13 cover four sides of the outer edge (the edge of the cavity 7a of the intermediate layer 7) of the hollow portion 9. The stress-relaxing layers 13 are interposed between the wiring electrode 12 and the support substrate 8 (the intermediate layer 7 of the support member).

The piezoelectric layer 2 is smaller than the outer edge (the edge of the cavity 7a of the intermediate layer 7) of the hollow portion 9. The stress-relaxing layers 13 at the four sides of the outer edge (the edge of the cavity 7a of the intermediate layer 7) of the hollow portion 9 cover the outer edge (the edge of the cavity 7a of the intermediate layer 7) of the hollow portion 9 except for corner portions of the four sides of the outer edge (the edge of the cavity 7a of the intermediate layer 7) of the hollow portion 9. Consequently, the four holes 9X that are in communication with the hollow portion 9 are exposed to the corner portions of the four sides of the outer edge (the edge of the cavity 7a of the intermediate layer 7) of the hollow portion 9. As for the acoustic wave device according to the modification to the fourth preferred embodiment, the stress-relaxing layers 13 relieve the stress between the support member and the piezoelectric layer 2, and cracking of the piezoelectric layer 2 is reduced or prevented. In FIG. 23, the stress-relaxing layers 13 are disposed so as to avoid the corner portions of the four sides. However, the stress-relaxing layers 13 may cover the corner portions of the four sides.

The preferred embodiments are described above to make the present disclosure easy to understand and do not limit the present disclosure. The present disclosure can be modified and altered without departing from the spirit thereof. The present disclosure includes equivalents.

For example, the functional electrode 30 may be a BAW element (Bulk Acoustic Wave Element) that includes an upper electrode and a lower electrode. The upper electrode and the lower electrode sandwich the piezoelectric layer 2 therebetween in the thickness direction.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate with a thickness in a first direction;
a piezoelectric layer above or below the support substrate;
a functional electrode on or above the piezoelectric layer; and
a stress-relaxing layer; wherein
in a plan view in the first direction, a hollow portion at least partly overlaps the functional electrode between the support substrate and the piezoelectric layer; and
in a plan view in the first direction, the stress-relaxing layer overlaps an outer edge of the hollow portion or is outside at least a portion of the outer edge of the hollow portion and is interposed between the support substrate and the piezoelectric layer.

2. The acoustic wave device according to claim 1, further comprising:
a wiring electrode that is electrically connected to the functional electrode; wherein
the stress-relaxing layer is interposed between the wiring electrode and the support substrate.

3. The acoustic wave device according to claim 1, wherein the stress-relaxing layer includes resin, metal, or a multilayer body of resin and metal.

4. The acoustic wave device according to claim 1, wherein
an intermediate layer is between the support substrate and the piezoelectric layer; and
an elastic modulus of the stress-relaxing layer is smaller than that of the intermediate layer.

5. The acoustic wave device according to claim 1, wherein
in a plan view in the first direction, the piezoelectric layer is smaller than the outer edge of the hollow portion; and
the stress-relaxing layer surrounds the piezoelectric layer and overlaps the outer edge of the hollow portion in a plan view in the first direction.

6. The acoustic wave device according to claim 1, wherein
in a plan view in the first direction, the piezoelectric layer is larger than the outer edge of the hollow portion; and
the stress-relaxing layer surrounds the hollow portion and is outside the outer edge of the hollow portion.

7. The acoustic wave device according to claim 5, wherein
an intermediate layer is between the support substrate and the piezoelectric layer; and
the hollow portion includes a recessed portion of the intermediate layer.

8. The acoustic wave device according to claim 1, wherein in a plan view in the first direction, the outer edge of the hollow portion is rectangular or substantially rectangular, and the stress-relaxing layer covers at least two sides of the outer edge of the hollow portion.

9. The acoustic wave device according to claim 8, wherein in a plan view in the first direction, the stress-relaxing layer covers two sides of the outer edge of the hollow portion that face each other.

10. The acoustic wave device according to claim 1, wherein
an intermediate layer is between the support substrate and the piezoelectric layer; and
a through-hole extends through the piezoelectric layer and is filled with the stress-relaxing layer.

11. The acoustic wave device according to claim 1, wherein
an intermediate layer is between the support substrate and the piezoelectric layer;
in a plan view in the first direction, the outer edge of the hollow portion is rectangular or substantially rectangular;
in a plan view in the first direction, the piezoelectric layer is smaller than the outer edge of the hollow portion; and
in a plan view in the first direction, the stress-relaxing layer covers the outer edge of the hollow portion except for a corner portion of the outer edge of the hollow portion.

12. The acoustic wave device according to claim 1, wherein the functional electrode includes one or more first electrode fingers that extend in a second direction that intersects with the first direction and one or more second electrode fingers that face any one of the one or more first electrode fingers in a third direction that intersects with the second direction, the one or more second electrode fingers extending in the second direction.

13. The acoustic wave device according to claim 11, wherein a thickness of the piezoelectric layer is about 2p or less where p is a distance between centers of a first electrode finger and a second electrode finger adjacent to each other among the one or more first electrode fingers and the one or more second electrode fingers.

14. The acoustic wave device according to claim 13, wherein the piezoelectric layer includes lithium niobate or lithium tantalate.

15. The acoustic wave device according to claim 14, wherein the acoustic wave device is structured to generate a bulk wave in a thickness-shear mode.

16. The acoustic wave device according to claim 12, wherein d/p≤0.5 is satisfied where d is a thickness of the piezoelectric layer, and p is a distance between centers of a first electrode finger and a second electrode finger adjacent to each other among the one or more first electrode fingers and the one or more second electrode fingers.

17. The acoustic wave device according to claim 16, wherein d/p is about 0.24 or less.

18. The acoustic wave device according to claim 12, wherein MR≤about 1.75 (d/p)+0.075 is satisfied where an overlapping region in a plan view in the third direction is an excitation region, and MR is a metallization ratio of the one or more first electrode fingers and the one or more second electrode fingers to the excitation region.

19. The acoustic wave device according to claim 12, wherein the acoustic wave device is structured to generate a plate wave.

12. The acoustic wave device according to claim 12,
the piezoelectric layer includes lithium niobate or lithium tantalate; and
Euler angles (φ, θ, ψ) of the lithium niobate or the lithium tantalate are within an expression (1), an expression (2) or an expression (3):
(0°±10°, 0° to 20°, freely selected ψ) (1)
(0°±10°, 20° to 80°, 0° to 60° (1−(θ−50)²/900)^{1/2}) or (0°±10°, 20° to 80°, [180°−60° (1−(θ−50)²/900)^{1/2}] to) 180°) (2)
(0°±10°, [180°−30° (1−(ψ−90)²/8100)^{1/2}] to 180°, freely selected ψ) (3).

21. A method of manufacturing an acoustic wave device, the method comprising:
stacking a support substrate with a thickness in a first direction and a piezoelectric layer;
forming a functional electrode in or on the piezoelectric layer after the stacking;
etching the piezoelectric layer in an outer region outside a region in which the functional electrode is formed;
forming a stress-relaxing layer such that the stress-relaxing layer at least partly overlaps the piezoelectric layer after the etching; and
forming a hollow portion such that the stress-relaxing layer is exposed.

22. The method according to claim 21, wherein in the forming the hollow portion, the support substrate is etched, and the hollow portion an outer edge of which is larger than the piezoelectric layer in a plan view in the first direction is formed from a surface of the support substrate opposite the piezoelectric layer.

23. The method according to claim 21, wherein
in the stacking, the support substrate and the piezoelectric layer sandwich an intermediate layer that partly includes a sacrificial layer therebetween so as to be stacked into one piece; and
in the forming the hollow portion, the sacrificial layer is etched, and the hollow portion an outer edge of which is larger than the piezoelectric layer in a plan view in the first direction is formed.
